(19) United States
(12) Patent Application Publication
(10) Pub. No.: US 2026/0128255 A1
(43) Pub. Date: May 7, 2026

(54) PARTICLE BEAM APPARATUS WITH MOVEABLE OBJECT STAGE

(71) Applicant: Carl Zeiss Microscopy GmbH, Jena (DE)

(72) Inventor: Holger Ebhart, Nattheim (DE)

(73) Assignee: Carl Zeiss Microscopy GmbH, Jena (DE)

(21) Appl. No.: 19/375,274

(22) Filed: Oct. 31, 2025

(30) Foreign Application Priority Data
Nov. 1, 2024 (DE) 10 2024 131 948.8

(51) Int. Cl. H01J 37/28; H01J 37/26

(52) U.S. Cl. CPC H01J 37/28; H01J 37/265; H01J 2237/006; H01J 2237/20221; H01J 2237/20285; H01J 2237/21; H01J 2237/225

(57) ABSTRACT

The invention relates to a method for operating a particle beam apparatus for imaging, processing and/or analysing an object. For example, the particle beam apparatus is embodied as an electron beam apparatus and/or an ion beam apparatus. The invention furthermore relates to a computer program product and to a system comprising a particle beam apparatus for carrying out the method. The method comprises providing first structure data and second structure data; determining a target arrangement for a first device; providing at least one movement path; modelling the movement path of the first device within the particle beam apparatus; carrying out a check to determine whether the modelling of the movement path has the result that at least one first surface arrangement of the first device and at least one second surface arrangement of the at least one second device, when carrying out a movement process, (i) have at least one common point or (ii) are at a shortest distance but do not have a common point, wherein the shortest distance is smaller than a predefinable minimum distance; and, depending on the result of the check, displaying a message, discarding a movement process, changing a speed of the movement process, aborting the movement process, switching the movement process to a further movement process and/or carrying out the movement process of the first device using a movement device for moving the first device.

### CROSS-REFERENCE TO RELATED APPLICATIIONS

This application claims the priority of German patent application no. 10 2024 131 948.8, filed on Nov. 1, 2024, which is incorporated by reference herein.

### TECHNICAL FIELD

This application relates to a method for operating a particle beam apparatus that images, processes, and/or analyses an object in a particle beam apparatus and more particularly to a computer program product and to a system having a particle beam apparatus for carrying out the method according to the system described herein.

### BACKGROUND

Electron beam apparatuses, in particular a scanning electron microscope (also referred to as SEM below) and/or a transmission electron microscope (also referred to as TEM below), are used to examine objects (also referred to as samples below) in order to gain insight into the properties and the behaviour under certain conditions.

In an SEM, an electron beam (also referred to as primary electron beam below) is generated by way of a beam generator and focused onto an object to be examined by way of a beam guiding system. By way of a guide device in the form of a scanning device, the primary electron beam is guided over a surface of the object to be examined. In the process, the electrons of the primary electron beam interact with the object to be examined. As a consequence of the interaction, in particular electrons are emitted by the object (so-called secondary electrons) and electrons of the primary electron beam are backscattered (so-called backscattered electrons). The secondary electrons and the backscattered electrons are detected and used for image generation. An image representation of the object to be examined is thus obtained. Furthermore, interaction radiation, for example x-ray radiation or cathodoluminescence, is generated during the interaction, and is detected by way of a detector and subsequently evaluated in order to analyse the object.

In the case of a TEM, a primary electron beam is likewise generated by way of a beam generator and guided onto an object to be examined by way of a beam guiding system. The primary electron beam radiates through the object to be examined. When the primary electron beam passes through the object to be examined, the electrons of the primary electron beam interact with the material of the object to be examined. The electrons passing through the object to be examined are imaged on a luminescent screen or on a detector (for example a camera) by a system consisting of an objective and a projection unit. Here, imaging may also take place in the scanning mode of a TEM. Usually, such a TEM is referred to as STEM. Additionally, the use of a further detector to detect electrons backscattered at the object to be examined and/or secondary electrons emitted by the object to be examined may be provided, in order to image the object to be examined.

Combining the function of a STEM and an SEM in a single particle beam apparatus is known. This particle beam apparatus may thus be used to carry out examinations of objects with an SEM function and/or with a STEM function.

Moreover, a particle beam apparatus with an ion beam column is known. Ions used for processing an object are generated by way of an ion beam generator arranged in the ion beam column. For example, material of the object is ablated, or material is applied to the object during the processing, for example with a gas being supplied. In addition or as an alternative thereto, the ions are used for imaging.

Furthermore, the prior art discloses the use of combination apparatuses for examining objects, in which both electrons and ions are able to be guided onto an object to be examined. For example, additionally equipping an SEM with an ion beam column is known. An ion beam generator arranged in the ion beam column is used to generate ions that are used for the preparation of an object (for example ablating material from the object or applying material to the object) or else for imaging. For this purpose, the ions are scanned over the object using a guide device in the form of a scanning device. The SEM serves here in particular to observe the preparation, but also for further examination of the prepared or unprepared object.

As explained above, backscattered electrons and secondary electrons emitted as a consequence of the interaction of the primary electron beam with the object may be detected and used for image generation. An image representation of the object is thus obtained. However, this image representation usually only depicts a spatially very restricted region of the object. For example, the region is smaller than 1 mm×1 mm, while the object usually has a size of at least 1 cm×1 cm. By way of example, even in the case of the abovementioned analysis of the object by way of a detector, it is possible to evaluate radiation only from the spatially very restricted region. Even in the case of the abovementioned processing of the object by way of ions from the ion beam generator of the particle beam apparatus with the ion beam column, it is possible to process only the spatially very restricted region.

Moving the object in the particle beam apparatus makes it possible to image, process and/or analyse further regions of the object. In addition or as an alternative, further objects may be imaged, processed and/or analysed when the object and/or a further object is moved relative to the beam column of the particle beam apparatus. A movement device is used to move the object in the particle beam apparatus. Moving the object in the particle beam apparatus makes it possible, in addition or as an alternative, to set different distances between an objective lens of the particle beam apparatus and the object, where the different distances are suitable for different settings of the particle beam apparatus. A further movement device is used to move the further object in the particle beam apparatus, for example. With regard to the further object, the movement of the further object and the further movement device, reference is made to the statements herein relating to the object, the movement of the object and the movement device, which are analogously applicable.

When the object is moved in the particle beam apparatus, the object may collide with yet another object, which is arranged for example in and/or on the particle beam apparatus, and/or with the particle beam apparatus itself. In the event of the object colliding with the yet another object, the object and/or the yet another object may be contaminated, damaged and/or destroyed. The collision between the object and the yet another object during operation of the particle beam apparatus is therefore undesirable. The yet another object may be embodied for example as the further object.

For the movement of the object in the particle beam apparatus, the object is arranged on the movement device; for example, the object is arranged on an object holder and/or on an object stage. The movement device may carry out the movement of the object, for example a translational movement and/or a rotational movement.

It is known from the prior art to arrange an object on an object holder. The object is arranged, by the object holder, on an object stage that is able to carry out at least one translational movement and at least one rotational movement. The object may be moved from a first position to a second position by at least one translational movement and/or by at least one rotational movement of the object stage.

Furthermore, it is known from the prior art to measure a three-dimensional shape of an object (sample) by way of a shape measurement and to store the measurements as first shape data. Based on the first shape data and second shape data, which relate to a three-dimensional shape of a sample chamber, a movement of the object is carried out so as to avoid a collision between the object and the sample chamber.

It is also known from the prior art to detect light rays emanating from a structure, to compute a surface model of the structure depending on the detected light rays, to determine a position and orientation of the surface model of the structure relative to an object region, to determine a measurement location relative to the surface model of the structure and to position an object depending on the computed surface model of the structure, on the determined position of the surface model of the structure, on the orientation of the surface model of the structure and on the determined measurement location. In this case, it is also possible to compute a surface model of a microscope section that is combined with the surface model of the structure to form a common surface model. The surface model of the structure may be used to position a location in the object region. The common surface model may be used to monitor a distance between the structure and the microscope section and thus to avoid collisions during a positioning process.

It is also known from the prior art to carry out a method that includes operating a particle beam apparatus in a 3D operating mode for capturing a three-dimensional representation of an object by lateral scanning (the scanning is carried out perpendicular to an optical axis of the particle beam apparatus) of a particle beam. The method is embodied here such that information from the three-dimensional representation, arising from the 3D operating mode, is linked to information arising from a high-resolution operating mode, such that it is easy for a user of the particle beam apparatus to recognize which regions of the object have already been examined. The method may also be used to find a measurement location again if the object has been moved relative to the particle beam apparatus, for example, or if the object has been removed from the particle beam apparatus and reinserted for a further examination.

With regard to the prior art, reference is made to U.S. Pat. No. 11,217,422 B2, JP 7008650 B2, EP 3 693 989 A1, DE 10 2010 046 902 A1 and U.S. Pat. No. 8,227,752 B1.

In order to avoid a collision between a first device and at least one second device during operation of a particle beam apparatus, it is known to embody the particle beam apparatus such that a control unit aborts a movement of the first device when the collision between the first device and the at least one second device is determined and/or predetermined. For this purpose, for example, data of the first device and/or of the at least one second device are captured and/or retrieved, where the data describe an external shape of the first device and/or of the at least one second device. By way of example, the first device is understood to be any element able to be arranged movably in and/or on the particle beam apparatus. By way of example, the at least one second device is understood to be any element able to be arranged in and/or on the particle beam apparatus. In addition or as an alternative, the particle beam apparatus is understood to be the at least one second device.

### SUMMARY OF THE INVENTION

It is desirable that it be easily possible to carry out a movement process of a device in a particle beam apparatus, possibly automatically.

The method according to the system described herein operates a particle beam apparatus that images, processes, and/or analyses an object. Object may in this case denote any element arranged in a sample chamber of the particle beam apparatus. The particle beam apparatus in particular has at least one beam generator that generates a particle beam that includes charged particles. For example, the charged particles are electrons or ions. The particle beam apparatus furthermore has for example a guide device that guides, shapes, and/or focuses the particle beam that includes charged particles onto the object.

Moreover, the particle beam apparatus in particular has a first device. By way of example, the object is embodied as the first device. By way of example, the first device is understood to be any element able to be arranged movably in and/or on the particle beam apparatus. The element is arranged movably when the element is able to be moved using at least one movement device. With regard to the at least one movement device, reference is made to the statements below.

The particle beam apparatus furthermore has for example at least one second device. By way of example, the at least one second device is understood to be any element able to be arranged in and/or on the particle beam apparatus. In addition or as an alternative, for example, the particle beam apparatus is understood to be the at least one second device.

Furthermore, the particle beam apparatus has for example at least one detector that detects interaction particles and/or interaction radiation. The interaction particles and/or interaction radiation arise/arises from an interaction of the particle beam with the object when the particle beam is incident on the object. As a consequence of the interaction, in particular electrons are emitted by the object (so-called secondary electrons) and electrons of the primary electron beam are backscattered (so-called backscattered electrons). The secondary electrons and the backscattered electrons are detected and used for image generation. An image representation of the object to be examined is thus obtained. Furthermore, interaction radiation, for example x-ray radiation or cathodoluminescence, is generated during the interaction, and is for example detected by way of the detector and subsequently evaluated in order to analyse the object.

Again furthermore, the particle beam apparatus has for example the at least one movement device to move the first device. The at least one movement device may in this case be designed to carry out at least one translational movement and/or to carry out at least one pivoting movement. With regard to the translational movement and/or the pivoting movement, reference is made to the statements below.

Furthermore, the particle beam apparatus has for example at least one control unit that receives control data and/or actuates the at least one movement device. Furthermore, the particle beam apparatus has for example at least one storage unit that stores data, in particular structure data and/or collision data. Moreover, the particle beam apparatus has for example a processor unit in which a computer program product having at least one of the features mentioned elsewhere herein or having a combination of at least two of the features mentioned elsewhere herein is loaded.

In other words, the at least one movement device may carry out at least one translational movement in at least one spatial direction and/or at least one pivoting movement about at least one axis of rotation. In this case, translational movement is understood to mean a linear movement in which all points of a body experience the same displacement. Pivoting movement is understood to mean a movement in which all points of the body move on circular paths about a common axis (the axis of rotation). In this case, during the pivoting movement, the movement does not have to result in a closed circular path about the common axis.

The method includes method steps, which are explained below.

In one method step of the method according to the system described herein, first structure data and second structure data are provided. The first structure data and the second structure data are discussed in more detail below.

The first structure data includes information about at least one first surface arrangement of the first device within the particle beam apparatus. In other words, by way of example, the at least one first surface arrangement of the first device may be described by the first structure data. The second structure data includes information about at least one second surface arrangement of at least one second device within the particle beam apparatus. In other words, by way of example, the at least one second surface arrangement of the at least one second device may be described by the second structure data.

Provision is furthermore made for example for the first surface arrangement to have a first space of finite extent, which partially or completely surrounds the first device. In other words, the first space of finite extent delimits the first surface arrangement. Proceeding from the first device, the first space of finite extent has for example an extent of up to 100 mm, of up to 50 mm, of up to 20 mm, of up to 10 mm, of up to 1 mm, of up to 500 μm, of up to 300 μm, of up to 100 μm or of up to 10 μm. However, the invention is not restricted to such extents. On the contrary, the extent of the first space of finite extent may have any value suitable for the invention. In particular, the extent of the first space of finite extent is variable. By way of example, the extent of the first space of finite extent is dependent on the speed of movement of the first device and/or of the at least one second device. In addition or as an alternative, the extent of the first space of finite extent is dependent on the distance between the first device and the at least one second device. Provision is made in particular for the extent of the first space of finite extent to become larger as the distance between the first device and the at least one second device increases, and for the extent of the first space of finite extent to become smaller as the distance between the first device and the at least one second device decreases. In addition or as an alternative, provision is made for the extent of the first space of finite extent to become larger as the speed of movement of the first device and/or of the at least one second device increases, and for the extent of the first space of finite extent to become smaller as the speed of movement of the first device and/or of the at least one second device decreases.

Provision is furthermore made for example for the second surface arrangement to have a second space of finite extent, which partially or completely surrounds the at least one second device. In other words, the second space of finite extent delimits the second surface arrangement. Proceeding from the at least one second device, the second space of finite extent has for example an extent of up to 100 mm, of up to 50 mm, of up to 20 mm, of up to 10 mm, of up to 1 mm, of up to 500 μm, of up to 300 μm, of up to 100 μm or of up to 10 μm. However, the invention is not restricted to such extents. On the contrary, the extent of the second space of finite extent may have any value suitable for the invention. In particular, the extent of the second space of finite extent is variable. By way of example, the extent of the second space of finite extent is dependent on the speed of movement of the first device and/or of the at least one second device. In addition or as an alternative, the extent of the second space of finite extent is dependent on the distance between the first device and the at least one second device. Provision is made in particular for the extent of the second space of finite extent to become larger as the distance between the first device and the at least one second device increases, and for the extent of the second space of finite extent to become smaller as the distance between the first device and the at least one second device decreases. In addition or as an alternative, provision is made for the extent of the second space of finite extent to become larger as the speed of movement of the first device and/or of the at least one second device increases, and for the extent of the second space of finite extent to become smaller as the speed of movement of the first device and/or of the at least one second device decreases.

By way of example, the first space of finite extent of the first surface arrangement and/or the second space of finite extent of the second surface arrangement are/is used when carrying out method steps of the method according to the system described herein, in particular in the check, explained below, carried out to determine whether, in a movement process of the first device, the first surface arrangement and the second surface arrangement have at least one common point. In particular, provision is made to check whether the first space of finite extent and the second space of finite extent have a common point.

Moreover, the first structure data and/or the second structure data include for example information about at least one transformation of the first device and/or of the at least one second device. The transformation of the first device and/or of the at least one second device within the meaning of the system described herein may be understood to mean for example a movement of the first device and/or of the at least one second device. During the movement, the first device and/or the at least one second device experiences the transformation, since a property of the first device and/or of the at least one second device, namely a positioning in a space, changes. In particular, the transformation may be understood to mean a movement of the first device and/or of the at least one second device along a movement path. In this case, the movement path, within the meaning of the system described herein, may be understood to mean a sequence of points in space, where the points are embodied such that it is possible to carry out a movement from a first point of the sequence of points to a last point of the sequence of points. In the movement from a first point of the sequence of points to a last point of the sequence of points, the points of the sequence of points may be run through in succession. By way of example, only part of the movement path may also be understood to be the movement path. In this case, only some of the points of the sequence of points are run through in the movement. Points of the sequence of points are also referred to below as intermediate points. In addition or as an alternative, the transformation of the first device and/or of the at least one second device within the meaning of the system described herein may be understood to mean a deformation of the first device and/or of the at least one second device. As an alternative, the transformation of the first device and/or of the at least one second device within the meaning of the system described herein might not be understood to mean a deformation of the first device and/or of the at least one second device. In this case, the transformation of the first device and/or of the at least one second device within the meaning of the system described herein is understood to mean the movement of the first device and/or of the at least one second device.

The deformation of the first device and/or of the at least one second device within the meaning of the system described herein may be understood to mean for example a change of the surface arrangement of the first device and/or of the at least one second device. In this case, the deformed device may for example remain at a position of the deformed device in space during the deformation. By way of example, during the deformation of the first device within the meaning of the system described herein, the surface arrangement of the first device may change, while a centre of mass of the first device is not spatially changed. In addition or as an alternative, the deformation of the first device and/or of the at least one second device within the meaning of the system described herein may be understood to mean an expansion and/or contraction. Within the meaning of the system described herein, the expansion is understood to mean an increase in spatial extent. Within the meaning of the system described herein, the contraction is understood to mean a decrease in spatial extent. The expansion may be a thermal expansion, for example. In other words, the expansion of the first device and/or of the at least one second device may be brought about by a temperature change of the first device and/or of the at least one second device. The contraction may be a thermal contraction, for example. In other words, the contraction of the first device and/or of the at least one second device may be brought about by the temperature change of the first device and/or of the at least one second device.

In addition or as an alternative, the deformation of the first device and/or of the at least one second device within the meaning of the system described herein may be understood to mean an elongation. Within the meaning of the system described herein, the elongation is understood to mean a change in length of the body on which at least one force acts. The elongation may in this case achieve shortening of the body or lengthening of the body. In addition or as an alternative, the deformation of the first device and/or of the at least one second device within the meaning of the system described herein may be understood to mean a torsion. Within the meaning of the system described herein, the torsion of the body is understood to mean twisting of the body. By way of example, two opposing torques act on the body, leading to twisting of the body.

Furthermore, in addition or as an alternative, the deformation of the first device and/or of the at least one second device within the meaning of the system described herein may include a change of the first device and/or of the at least one second device itself. By way of example, the change of the first device includes a movement of a first part of the first device relative to a second part of the first device. If the first device is embodied for example as a movable manipulator, a change of the movable manipulator may include a movement of a wire of the movable manipulator relative to a body of the movable manipulator.

As explained above, the first structure data and the second structure data are provided in the abovementioned method step of the method according to the system described herein. Provision of the first structure data and of the second structure data may take place in at least one of at least three possible variants.

In a first variant of providing the first structure data and/or the second structure data, the first structure data and/or the second structure data are retrieved from a storage unit for the particle beam apparatus. By way of example, the storage unit is assigned to the particle beam apparatus and/or arranged on the particle beam apparatus. In addition or as an alternative, the storage unit is arranged separately from the particle beam apparatus. In particular, provision is made for the storage unit to be able to be signal-connected and/or radio-connected to the particle beam apparatus. In this case, the storage unit is embodied such that the storage unit is suitable for storing data and for retrieving data. In other words, the storage unit stores data corresponding to the first structure data and/or the second structure data. Data corresponding to the first structure data and/or the second structure data may be retrieved from the storage unit. In addition or as an alternative, the first structure data and/or the second structure data may be computed from data stored in the storage unit.

In a second variant of providing the first structure data and/or the second structure data, the first structure data and/or the second structure data are input into the control unit of the particle beam apparatus by a user of the particle beam apparatus using an input unit. The control unit is in this case embodied such that the control unit is suitable for controlling the particle beam apparatus. By way of example, the control unit is embodied to actuate the at least one movement device and/or to actuate a guide device of the particle beam apparatus. As mentioned above, the user of the particle beam apparatus performs the input using the input unit of the particle beam apparatus. The input unit is in this case embodied such that the input unit is suitable for inputting data. By way of example, the input unit is embodied as a keyboard and/or as a joystick and/or as at least one sensor that transmits data into the control unit and/or as at least one detector that transmits data into the control unit. In addition or as an alternative, the input unit may be embodied as a camera that is designed, using a computer program, to capture gestures made by the user and to interpret the gestures as data. Furthermore, in addition or as an alternative, the input unit may be embodied as a unit that allows desired data to be read from a file. In other words, the first structure data and/or the second structure data are provided using the input unit.

In a third variant of providing the first structure data and/or the second structure data, the first structure data and/or the second structure data are recorded using at least one detector that records structure data and/or at least one sensor that records structure data of the particle beam apparatus. By way of example, the detector that records structure data may correspond to the detector of the particle beam apparatus as mentioned above. The detector that records structure data is in this case embodied such that the detector is designed to detect interaction particles and/or interaction radiation. The interaction particles and/or interaction radiation arise/arises from an interaction of the particle beam with the first and/or with the at least one second device when the particle beam is incident on the first and/or the at least one second device. As a consequence of the interaction, in particular electrons are emitted by the first and/or the at least one second device (so-called secondary electrons) and electrons of the primary electron beam are backscattered (so-called backscattered electrons). The secondary electrons and the backscattered electrons are detected and used for image generation. An image representation of the first device to be examined and/or of the at least one second device to be examined is thus obtained. Furthermore, interaction radiation, for example x-ray radiation or cathodoluminescence, is generated during the interaction, and is for example detected by way of the detector that records structure data and subsequently evaluated in order to analyse the first device and/or the at least one second device. The sensor that records structure data is embodied such that the sensor is designed to capture physical properties of the first and/or of the at least one second device. By way of example, the sensor that records structure data may capture electromagnetic radiation scattered at the first and/or the at least one second device. In particular, the electromagnetic radiation may in this case include at least one wavelength from a wavelength range from 400 nm to 2000 nm.

It is pointed out that the first structure data and the second structure data may be provided using various ones of the abovementioned variants. In other words, the first structure data may be provided by the variant that does not correspond to the variant used to provide the second structure data. By way of example, the first structure data are provided by recording the first structure data using the at least one detector that records structure data, and the second structure data are provided by retrieving the second structure data from the storage unit of the particle beam apparatus.

The first and/or the second structure data may be provided for example in the form of CAD data. In other words, there may be CAD models from which information relating to the first structure data and/or the second structure data may be taken.

In a further method step of the method according to the system described herein, a target arrangement for the first device is determined using the control unit of the particle beam apparatus. In this case, the target arrangement within the meaning of the system described herein is for example a relative arrangement of the first device with respect to the at least one second device. In other words, the target arrangement specifies for example a desired arrangement to be achieved of the first device with respect to the at least one second device. By way of example, the target arrangement for the first device is determined by inputting target data into the control unit of the particle beam apparatus and/or by loading the target data from the storage unit into the control unit of the particle beam apparatus. In particular, target data are input using the input unit or an input device for the control unit. The target data within the meaning of the system described herein are suitable for defining the target arrangement. By way of example, the target data includes spatial coordinates of the first device relative to the at least one second device, where the spatial coordinates of the first device relative to the at least one second device describe at least one position of the first device relative to the at least one second device in the target arrangement. In addition or as an alternative, the target arrangement for the first device may be determined by capturing target data by way of the at least one sensor and/or the at least one detector. Furthermore, in addition or as an alternative, the target arrangement for the first device may be determined by computing target data using the control unit of the particle beam apparatus. By way of example, the target data may be computed using a computer program that applies image recognition methods using the control unit of the particle beam apparatus. With regard to the control unit and the input unit, reference is made to the above statements, which are analogously applicable here as well.

In a further method step of the method according to the system described herein, at least one movement path of the first device to reach the target arrangement for the first device is provided using the processor unit. With regard to the movement path, reference is made to the above statements, which are analogously applicable here as well. By way of example, the processor unit is assigned to the particle beam apparatus and/or arranged on the particle beam apparatus.

Providing the movement path includes determining the movement path, for example by defining the intermediate points, where the intermediate points are points in space that are able to be used to describe the movement path (in this respect, see also the above statements regarding the movement path). By way of example, the intermediate points may be described by spatial coordinates. The movement path may be determined for example by the shortest distance between the intermediate points.

When providing the movement path, for example, the processor unit generates data describing movement paths. By way of example, the data describe a multiplicity of movement paths. In particular, an individual movement path may be selected from the multiplicity of movement paths. The individual movement path may be selected from the multiplicity of movement paths for example based on predefinable criteria. The predefinable criteria for selecting the individual movement path may be formed for example by a length of the individual movement path, a duration of a movement process associated with the individual movement path, a distance between the individual movement path and surrounding devices and/or a location of the individual movement path. A movement process within the meaning of the system described herein is understood here to mean carrying out a movement. In other words, for example, the movement of the first device along the movement path is referred to as a movement process. By way of example, the movement process is controlled by the control unit of the particle beam apparatus using the at least one movement device. In other words, the movement process is carried out for example in automated fashion. The at least one movement device is suitable for moving the first device in the particle beam apparatus (in this respect, see also the statements provided elsewhere herein relating to the at least one movement device). By way of example, the first device is arranged on the at least one movement device in the form of an object holder and/or an object stage. The at least one movement device may carry out the movement of the first device, for example a translational movement and/or a pivoting movement.

In a further method step of the method according to the system described herein, the at least one movement path of the first device within the particle beam apparatus is modelled using the processor unit. In other words, the movement path is modelled computationally. The provision of the movement path and the modelling of the movement path may be contained within a single method step or be identical.

The first structure data, the second structure data and the target arrangement for the first device are used for the modelling. With regard to the movement path, reference is made to the above statements, which are analogously applicable here as well. The processor unit of the particle beam apparatus is designed to carry out computing operations and/or to execute programs. In particular, part of the movement path may also be understood to be the movement path within the meaning of the system described herein. Modelling the movement path within the meaning of the system described herein includes determining the movement path. In other words, the modelling may be understood to mean simulating the movement path.

The provision and/or modelling of the at least one movement path of the first device within the particle beam apparatus using the processor unit may be repeated. By way of example, the provision and/or modelling of the at least one movement path of the first device within the particle beam apparatus using the processor unit may be repeated when a user of the particle beam apparatus makes an input, where the input aims to repeat the modelling. By way of example, the inputting of a new target arrangement using the input unit may target the repetition of the provision and/or of the modelling.

In a further method step of the method according to the system described herein, the processor unit is used, on the one hand, to check whether the modelling of the movement path of the first device within the particle beam apparatus has the result, at at least one point of the modelled movement path, that the at least one first surface arrangement of the first device and the at least one second surface arrangement of the at least one second device have at least one common point when carrying out a movement process along the modelled movement path. On the other hand, in the method step of the method according to the system described herein, a check is carried out to determine whether the modelling of the movement path of the first device within the particle beam apparatus has the result that the at least one first surface arrangement of the first device and the at least one second surface arrangement of the at least one second device are at a shortest distance from one another when carrying out the movement process along the modelled movement path, where the shortest distance is smaller than a predefinable minimum distance, and where the at least one first surface arrangement of the first device and the at least one second surface arrangement of the at least one second device do not, however, have a common point when carrying out the movement process along the modelled movement path. Within the meaning of the system described herein, a distance between a first body and a second body is understood to mean a shortest connection of all possible connections between any point on a surface of the first body and any point on a surface of the second body. Of all distances between the at least one first surface arrangement of the first device and the at least one second surface arrangement of the at least one second device that are achieved when carrying out the movement process along the modelled movement path, a smallest possible distance is referred to as a shortest distance. The predefinable minimum distance may be provided for example through retrieval from the storage unit and/or by an input from the user of the particle beam apparatus using the input unit. By way of example, the predefinable minimum distance is not less than 10 um.

In other words, in the abovementioned method step of the method according to the system described herein, a check is carried out to determine whether there is a match between at least one first point of the at least one first surface arrangement of the first device and at least one second point of the at least one second surface arrangement of the at least one second device, when the movement process is carried out along the modelled movement path. Moreover, a check is carried out to determine whether, during the movement process along the modelled movement path, there is a state in which the shortest distance between the at least one first surface arrangement of the first device and the at least one second surface arrangement of the at least one second device falls below the predefinable minimum distance. In other words, a check is carried out to determine whether the at least one first surface arrangement of the first device and the at least one second surface arrangement of the at least one second device, when carrying out the movement process along the modelled movement path, approach closer to one another than specified by the predefinable minimum distance. The predefinable minimum distance may for example be retrieved from the storage unit. In addition or as an alternative, the predefinable minimum distance may be determined by the input from the user of the particle beam apparatus using the input unit.

In a further method step of the method according to the system described herein, a distinction is made based on the result of the check in the abovementioned method step.

If the at least one first surface arrangement of the first device and the at least one second surface arrangement of the at least one second device have the at least one common point when carrying out the movement process along the modelled movement path, at least one of the following method steps is carried out in the further method step of the method according to the system described herein:
(a) displaying a message on a display unit of the particle beam apparatus;
(b) discarding or aborting the movement process of the first device along the provided movement path. If the movement process of the first device along the provided movement path has not yet been started, the movement process is accordingly not initiated. However, if the movement process of the first device along the provided movement path has already been started, the movement process is aborted;
(c) discarding or switching the movement process of the first device along the provided movement path to a further movement process. If the movement process of the first device along the provided movement path has not yet been started, the movement process is accordingly not initiated. However, if the movement process of the first device along the provided movement path has already been started, the movement process is switched to a further movement process. By way of example, the switching of the movement process of the first device includes restricting the further movement process to predefinable degrees of freedom of the movement of the first device, in particular to one or more predefinable translational movements and/or rotational movements;
(d) carrying out the movement process of the first device along the provided movement path using the at least one movement device to move the first device;
(e) changing a speed of the movement process of the first device along the provided movement path using the movement device to move the first device.

The abovementioned further movement process may be for example a manual movement process, that is to say a movement process in which the movement is controlled by an input from the user. In addition or as an alternative, the further movement process may be a movement process of the first device along a further movement path, where the further movement path arises from the provided movement path, for example, such that the further movement path is a displacement or rotation of the provided movement path. By way of example, the further movement path arises from the provided movement path such that all points of the provided movement path are displaced in a direction, for example a direction parallel to an optical axis of the particle beam apparatus.

The abovementioned display unit within the meaning of the system described herein is designed to display data. By way of example, the display unit is used to communicate, to the user of the particle beam apparatus, information stating that the at least one first surface arrangement of the first device and the at least one second surface arrangement of the at least one second device have the at least one common point when carrying out the movement process along the modelled movement path.

The abovementioned aborting of the movement process of the first device along the provided movement path includes for example stopping the movement process of the first device along the provided movement path. In addition or as an alternative, aborting the movement process of the first device along the provided movement path includes for example not starting the movement process of the first device along the provided movement path.

In the abovementioned switching of the movement process of the first device along the provided movement path to the further movement process, there is no further control of the movement process of the first device along the provided movement path using the target data.

In the abovementioned further movement process within the meaning of the system described herein, the first device is moved for example by the input from the user of the particle beam apparatus using the input unit and the control unit. In other words, for example, the user of the particle beam apparatus controls the movement of the first device. Switching the movement process of the first device along the provided movement path to the further movement process includes for example aborting the movement process of the first device along the provided movement path.

In the abovementioned carrying out of the movement process of the first device along the provided movement path, for example, the first device and the at least one second device may be brought into contact, since the at least one first surface arrangement of the first device and the at least one second surface arrangement of the at least one second device have the at least one common point when carrying out the movement process along the modelled movement path.

A decision as to whether, as a result of the abovementioned identification that the at least one first surface arrangement of the first device and the at least one second surface arrangement of the at least one second device have the at least one common point when carrying out the movement process along the modelled movement path, at least one of method steps (a) to (e) is carried out (that is to say (a) displaying the message on the display unit of the particle beam apparatus and/or (b) discarding or aborting the movement process of the first device along the provided movement path and/or (c) discarding or switching the movement process of the first device along the provided movement path to a further movement process and/or (d) carrying out the movement process of the first device along the provided movement path and/or (e) changing a speed of the movement process of the first device along the provided movement path using the movement device to move the first device) may be stored for example in the storage unit. In other words, the storage unit contains for example information such that the message is always displayed on the display unit of the particle beam apparatus and the movement process of the first device along the provided movement path is always aborted as soon as the check has the result that the at least one first surface arrangement of the first device and the at least one second surface arrangement of the at least one second device have the at least one common point when carrying out the movement process along the modelled movement path. In addition or as an alternative, the decision may be made by the user of the particle beam apparatus. In this case, for example, the message is displayed on the display unit of the particle beam apparatus, linked to at least one selection option as to whether the movement process of the first device along the provided movement path should be discarded and/or the movement process of the first device along the provided movement path should be aborted and/or the movement process of the first device along the provided movement path should be switched to a further movement process and/or a speed of the movement process of the first device along the provided movement path should be changed. The displaying of the message may include for example information about the arrangement, an expected distance between the first device and the at least one second device, a visualization of the arrangement and/or a warning message. By making an input using the input unit, the user of the particle beam apparatus may make a selection from the at least one selection option. In addition or as an alternative, the user of the particle beam apparatus may select to carry out the movement process of the first device along the provided movement path, for example in order to deliberately bring the first device into mechanical contact with the at least one second device.

When a first location of the at least one first surface arrangement of the first device and a second location of the at least one second surface arrangement of the at least one second device are at the shortest distance when carrying out the movement process along the modelled movement path, where the shortest distance is smaller than the predefinable minimum distance and where the at least one first surface arrangement of the first device and the at least one second surface arrangement of the at least one second device do not, however, have the common point when carrying out the movement process along the modelled movement path, at least one of the following method steps is carried out in the further method step of the method according to the system described herein:
(a) displaying the message on the display unit of the particle beam apparatus;
(b) discarding the movement process of the first device along the provided movement path or changing a speed of the movement process of the first device along the provided movement path. If the movement process of the first device along the provided movement path has not yet been started, the movement process is accordingly not initiated. However, if the movement process of the first device along the provided movement path has already been started, the speed of the movement process of the first device along the provided movement path is changed. By way of example, the speed is changed as a function of the shortest distance. In particular, the speed becomes lower the smaller the distance between the first device and the second device;
(c) discarding the movement process of the first device along the provided movement path or aborting the movement process of the first device along the provided movement path. If the movement process of the first device along the provided movement path has not yet been started, the movement process is accordingly not initiated. However, if the movement process of the first device along the provided movement path has already been started, the movement process of the first device along the provided movement path is aborted;
(d) discarding the movement process of the first device along the provided movement path or switching the movement process of the first device along the provided movement path to a further movement process. If the movement process of the first device along the provided movement path has not yet been started, the movement process is accordingly not initiated. However, if the movement process of the first device along the provided movement path has already been started, the movement process of the first device along the provided movement path is switched to a further movement process. By way of example, the switching of the movement process of the first device includes restricting the further movement process to predefinable degrees of freedom of the movement of the first device, in particular to one or more predefinable translational movements and/or rotational movements;
(e) carrying out the movement process of the first device along the provided movement path using the at least one movement device to move the first device.

With regard to the displaying of the message on the display unit of the particle beam apparatus, the discarding of the movement process of the first device along the provided movement path, the aborting of the movement process of the first device along the provided movement path, the switching of the movement process of the first device along the provided movement path to a further movement process and the carrying out of the movement process of the first device along the provided movement path, reference is made to the above statements, which are analogously applicable here as well. When changing the speed of the movement process of the first device along the movement path, the first device is moved, for example using the at least one movement device, more slowly and/or more quickly in comparison with a customary speed of the movement process along the provided movement path. By way of example, the speed is changed as a function of the shortest distance. The customary speed of the movement process and/or the changed speed of the movement process are/is stored for example in the storage unit. In addition or as an alternative, the customary speed of the movement process and/or the changed speed of the movement process may be predefined by the input from the user of the particle beam apparatus.

A decision as to whether, as a result of the abovementioned identification that the first location of the at least one first surface arrangement of the first device and the second location of the at least one second surface arrangement of the at least one second device are at the shortest distance when carrying out the movement process along the modelled movement path, where the shortest distance is smaller than the predefinable minimum distance and where the at least one first surface arrangement of the first device and the at least one second surface arrangement of the at least one second device do not, however, have the common point when carrying out the movement process along the modelled movement path, at least one of method steps (a) to (e) is carried out (that is to say (a) displaying the message on the display unit of the particle beam apparatus and/or (b) discarding the movement process of the first device along the provided movement path or changing the speed of the movement process of the first device along the provided movement path and/or (c) discarding the movement process of the first device along the provided movement path or aborting the movement process of the first device along the provided movement path and/or (d) discarding the movement process of the first device along the provided movement path or switching the movement process of the first device along the provided movement path to a further movement process and/or (e) carrying out the movement process of the first device along the provided movement path using the at least one movement device to move the first device) may be stored for example in the storage unit and/or be determined by the input from the user of the particle beam apparatus. With regard to the storage of the decision in the storage unit and the decision by the user of the particle beam apparatus, reference is made to the above statements, which are analogously applicable here as well.

When the at least one first surface arrangement of the first device and the at least one second surface arrangement of the at least one second device are at the shortest distance when carrying out the movement process along the modelled movement path, where the shortest distance is greater than or identical to the predefinable minimum distance and where the at least one first surface arrangement of the first device and the at least one second surface arrangement of the at least one second device thus also do not have the common point when carrying out the movement process along the modelled movement path, the movement process of the first device along the provided movement path is carried out using the at least one movement device to move the first device.

The system described herein is based on the following surprising insight. A movement path of a first device is modelled based on the provided structure data of the first device and of at least one second device and on the determined target arrangement of the first device. A check is carried out to determine whether the modelling of the movement path of the first device within the particle beam apparatus has the result, at at least one point of the movement path, when carrying out a movement process of the first device along the modelled movement path, that (i) there is a collision between the first device and the at least one second device in the particle beam apparatus, and/or whether (ii) a shortest distance between the first device and the at least one second device falls below a predefinable minimum distance, where, however, there is no collision between the first device and the at least one second device in the particle beam apparatus. The result of the check may be stored. Depending on the result of the check, (a) a message is displayed on a display unit of the particle beam apparatus and/or (b) the movement process of the first device along the movement path is discarded or a speed of the movement process of the first device along the movement path is changed and/or (c) the movement process of the first device along the movement path is discarded or the movement process of the first device along the movement path is aborted and/or (d) the movement process of the first device along the movement path is discarded or the movement process of the first device along the movement path is switched to a further movement process and/or (e) the movement process of the first device along the movement path is carried out using a movement device to move the first device. The system described herein makes it possible to carry out the movement of the first device along the movement path in suitable fashion based on the provided structure data and on the determined target arrangement. The system described herein thus makes it possible to carry out the movement of the first device along the movement path such that the first device does not collide with the at least one second device within the particle beam apparatus and/or with the particle beam apparatus itself. The system described herein makes it possible to avoid collisions with regard to the first device with the at least one second device within the particle beam apparatus and/or with the particle beam apparatus itself, where such a collision may lead to contamination, damage and/or destruction of the first device and/or of the at least one second device. The system described herein thus makes it possible to avoid making the first device and/or the at least one second device unusable. The system described herein also, by determining a target arrangement, enables contact between a micromanipulator and a lamella, for example. By way of example, the micromanipulator may be brought into contact with the lamella if the determined target arrangement corresponds to a location of the lamella or a location of the micromanipulator. Again furthermore, the system described herein enables the first device to be intentionally brought into contact with the at least one second device. It is thereby possible for example to produce a mechanical connection. In addition or as an alternative, it is thereby possible to produce an electrical connection.

The method according to the system described herein is also used in particular when the first device is already being moved in the sample chamber of the particle beam apparatus and an at least second device is introduced into the sample chamber of the particle beam apparatus only while the first device is moving. Furthermore, the method according to the system described herein is also used in particular when the first device is already being moved in the sample chamber of the particle beam apparatus and the at least one second device is moved in the sample chamber while the first device is moving. In this respect, the method according to the system described herein is also applicable when the first device and/or the at least second device are/is already being moved.

The method according to the system described herein is also used in particular when the first device is already being moved in the sample chamber of the particle beam apparatus and the direction of movement of the first device is changed while the first device is moving. As soon as a change of the direction of movement of the first device is identified, the method according to the system described herein is carried out in part or in full.

In one embodiment of the method according to the system described herein, in addition or as an alternative, a result of the check is stored in the storage unit as collision data. In other words, information about the check explained above is stored in the storage unit as the collision data. With regard to the storage unit, reference is made to the above statements. By way of example, the collision data includes information about the common point along the modelled movement path that both the at least one first surface arrangement of the first device and the at least one second surface arrangement of the at least one second device have when carrying out the movement process along the modelled movement path. By way of example, the collision data includes information about the shortest distance between the at least one first surface arrangement of the first device and the at least one second surface arrangement of the at least one second device that is achieved during the movement process along the modelled movement path and falls below the predefinable minimum distance. By way of example, the stored collision data may be displayed on the display unit.

In a further embodiment of the method according to the system described herein, provision is made, in addition or as an alternative, for at least one of the following units to be used as the first device and/or as the at least one second device: the object, the object stage, the object holder, a micromanipulator, the sample chamber, a lock, a light source, a beam column, a capture device (for example the detector that records structure data and/or the sensor that records structure data and/or any detector arranged on the particle beam apparatus), a gas injection system, a charge compensation device, a camera, a lock bar, a gripper, a scanning system (for example in the form of at least one condenser lens and/or in the form of at least one objective lens and/or in the form of at least one deflection unit), an electrode, a cable, a hose, a scanning force microscope, a microtome, a plasma cleaner, a Faraday cup, an aperture unit, an objective cap, at least part of the beam column, and the particle beam apparatus. In other words, any element within the particle beam apparatus and/or the particle beam apparatus itself that is suitable within the meaning of the system described herein may be used as the first device and/or as the at least one second device. An element within the meaning of the system described herein is suitable as the first device if the element is able to be arranged movably within the particle beam apparatus. By way of example, the element within the meaning of the system described herein is suitable as a first device if the element is designed such that the element moves relative to another element using the object stage. In this case, the movement may be automated, for example by virtue of the movement being carried out using the control unit. In addition or as an alternative, the movement may be manual, for example if the movement is carried out through manual actuation of the user of the particle beam apparatus. An element within the meaning of the system described herein is suitable as the at least one second device if the element is able to be arranged within the particle beam apparatus and/or is the particle beam apparatus. By way of example, the at least one second device may also be arranged only partially within the particle beam apparatus, for example if the at least one second device is embodied as the lock. In particular, an element within the meaning of the system described herein is suitable as the at least one second device if, owing to the movement of the first device, the first device and the at least one second device may collide and/or be at the shortest distance that falls below the predefinable minimum distance.

In yet another embodiment of the method according to the system described herein, provision is made, in addition or as an alternative, for the movement path of the first device within the particle beam apparatus to be provided and/or modelled taking into account a predefinable minimum distance, such that a distance between the first device and the at least one second device always corresponds at least to the predefinable minimum distance. In other words, the movement path of the first device within the particle beam apparatus is provided and/or modelled such that any distance between a first position on the at least one first surface arrangement of the first device and a second position on the at least one second surface arrangement of the at least one second device does not fall below the minimum distance when carrying out the movement process along the modelled movement path. In yet other words, the movement path of the first device within the particle beam apparatus is provided and/or modelled such that there is no collision between the first device and the at least one second device, and the first device and the at least one second device are at a distance from one another, at all times, that corresponds at least to the minimum distance. It is pointed out that a distance within the meaning of the system described herein denotes a physical distance. In other words, the distance within the meaning of the system described herein may be greater than zero if the first device and the at least one second device are not in contact with one another. Within the meaning of the system described herein, the distance may be zero if the first device and the at least one second device are in contact with one another. Within the meaning of the system described herein, the distance may be less than zero if the first device and the at least one second device are in contact with one another and a pressure is also exerted between the first device and the at least one second device. By way of example, the first device and the at least one second device, by carrying out the movement process, may be arranged on one another such that the first device is arranged with pressure on the at least one second device, for example in order to achieve a connection between the first device and the at least one second device.

The minimum distance may be for example the predefinable minimum distance. In this case, the movement path of the first device within the particle beam apparatus is provided and/or modelled such that the first device is always at a shortest distance from the at least one second device that is greater than the predefinable minimum distance. The minimum distance may be provided for example through retrieval from the storage unit and/or by an input from the user of the particle beam apparatus using the input unit. By way of example, the minimum distance is not less than 10 μm. With regard to the shortest distance and the minimum distance, reference is made to the above statements, which are analogously applicable here as well.

Furthermore, in addition or as an alternative, the method according to the system described herein may have at least one feature mentioned herein or a combination of at least two of the features mentioned herein.

None of the embodiments of the method according to the system described herein are restricted to the orders of the method steps presented above. On the contrary, any orders of the method steps suitable for solving the problem within the meaning of the system described herein may be used. As an alternative or in addition, provision is also made for the parallel implementation of at least two method steps. As an alternative or in addition, provision is also made for the omission of individual method steps.

The system described herein also relates to a computer program product that includes program code that is able to be loaded or is loaded into a processor unit of a particle beam apparatus, where the program code, when executed in the processor unit, controls the particle beam apparatus such that a method having at least one of the features described herein or having a combination of at least two of the features described herein is carried out. In other words, the system described herein also relates to a non-volatile and computer-readable medium that includes software that is able to be loaded or is loaded into a processor unit of a particle beam apparatus, where the software, when executed in the processor unit, controls the particle beam apparatus such that a method having at least one of the features described herein or having a combination of at least two of the features described herein is carried out. The software includes executable code that carries out at least one of the method steps described herein. In this respect, the system described herein also relates to a processor unit arranged on a particle beam apparatus and designed to carry out a method having at least one of the features described herein or having a combination of at least two of the features described herein.

The system described herein furthermore relates to a system that includes a storage unit that stores structure data and includes a particle beam apparatus that images, processes, and/or analyses an object, where the particle beam apparatus is explained elsewhere herein, as briefly summarized below.

The particle beam apparatus has at least one beam generator that generates at least one particle beam that includes charged particles. The charged particles are electrons and/or ions, for example. The particle beam apparatus has a first device. By way of example, the object is embodied as the first device. By way of example, the first device is understood to be any element able to be arranged movably in and/or on the particle beam apparatus.

The element is arranged movably when the element is able to be moved using at least one movement device. With regard to the at least one movement device, reference is made to the statements below. The particle beam apparatus furthermore has at least one second device. By way of example, the at least one second device is understood to be any element able to be arranged in and/or on the particle beam apparatus. In addition or as an alternative, the particle beam apparatus is understood to be the at least one second device. Again furthermore, the particle beam apparatus has at least one guide device that guides, shapes, and/or focuses the particle beam including charged particles onto the object. Furthermore, the particle beam apparatus has for example at least one detector that detects interaction particles and/or interaction radiation. The interaction particles and/or interaction radiation arise/arises from an interaction of the particle beam with the object when the particle beam is incident on the object. As a consequence of the interaction, in particular electrons are emitted by the object (so-called secondary electrons) and electrons of the primary electron beam are backscattered (so-called backscattered electrons). The secondary electrons and the backscattered electrons are detected and used for image generation. An image representation of the object to be examined is thus obtained. Furthermore, interaction radiation, for example x-ray radiation and/or cathodoluminescence, is generated during the interaction, and is for example detected by way of a detector and subsequently evaluated in order to analyse the object. Again furthermore, the particle beam apparatus has the at least one movement device to move the first device. The at least one movement device may in this case be designed to carry out at least one translational movement and/or to carry out at least one pivoting movement. With regard to the translational movement and/or the pivoting movement, reference is made to the above statements, which are analogously applicable here as well. Furthermore, the particle beam apparatus according to the system described herein has at least one control unit in particular that receives control data and/or in particular that actuates the at least one movement device and/or in particular that inputs the structure data. Furthermore, the particle beam apparatus has for example at least one storage unit that stores data, in particular structure data and/or collision data. Moreover, the particle beam apparatus has a processor unit in which a computer program product having the features already mentioned above is loaded.

In one embodiment of the particle beam apparatus, provision is made, in addition or as an alternative, for the particle beam apparatus to have at least one display unit that outputs messages and/or at least one detector that records structure data and/or at least one sensor that records structure data. By way of example, the detector that records structure data and/or the sensor that records structure data is designed to capture at least one first surface arrangement of the first device and/or at least one second surface arrangement of the at least one second device. By way of example, the detector that records structure data is embodied as an optical camera. By way of example, the sensor that records structure data is embodied as a light sensor, a LIDAR sensor and/or an ultrasonic sensor.

In a further embodiment of the system according to the system described herein, provision is made, in addition or as an alternative, for the first device and/or the at least one second device to be embodied as at least one of the following units: as the at least one object, as an object stage, as an object holder, as a micromanipulator, as a sample chamber, as a lock, as a light source, as a beam column, as a capture device, as a gas injection system, as a charge compensation device, as a camera, as a lock bar, as a gripper, as a scanning system (for example in the form of at least one condenser lens and/or in the form of at least one objective lens and/or in the form of at least one deflection unit), as an electrode, as a cable, as a hose, as a scanning force microscope, as a microtome, as a plasma cleaner, as a Faraday cup, as an aperture unit, as an objective cap, as at least part of the beam column, and as the particle beam apparatus. In this case, the capture device may be for example the detector that records structure data and/or the sensor that records structure data. In addition or as an alternative, the capture device may be any detector arranged in and/or on the particle beam apparatus. In other words, any element within the particle beam apparatus and/or the particle beam apparatus itself that is suitable within the meaning of the system described herein may be used as the first device and/or as the at least one second device. An element within the meaning of the system described herein is suitable as the first device if the element is able to be arranged movably within the particle beam apparatus. By way of example, the element within the meaning of the system described herein is suitable as a first device if the element is designed such that the element moves relative to another element using the object stage. In this case, the movement may be automated, for example by virtue of the movement being carried out using the control unit. In addition or as an alternative, the movement may be manual, for example if the movement is carried out through manual actuation of the user of the particle beam apparatus. An element within the meaning of the system described herein is suitable as the at least one second device if the element is able to be arranged within the particle beam apparatus and/or is the particle beam apparatus. In particular, an element within the meaning of the system described herein is suitable as the at least one second device if, owing to the movement of the first device, the first device and the at least one second device may collide and/or be at a shortest distance that falls below a predefinable minimum distance.

In yet another embodiment of the system described herein, provision is made, in addition or as an alternative, for the beam generator to be embodied as a first beam generator. In this case, the particle beam is embodied as a first particle beam including first charged particles, and the guide device is embodied as a first guide device that guides, shapes, and/or focuses the first particle beam onto a region within the sample chamber. The region within the sample chamber may in this case in particular be the object and/or a region on the object. Furthermore, the particle beam apparatus has at least one second beam generator that generates at least one second particle beam including second charged particles and at least one second guide device that guides, shapes, and/or focuses the at least one second particle beam onto the region within the sample chamber. The second guide device may be embodied for example as a second scanning device and/or as a second objective lens.

In a further embodiment of the system described herein, provision is made for the particle beam apparatus to be an electron beam apparatus and/or an ion beam apparatus.

### BRIEF DESCRIPTION OF DRAWINGS

Further practical embodiments and advantages of the system described herein are described below in association with the drawings, in which:

FIG. 1 shows a schematic illustration of a first particle beam apparatus;

FIG. 1A shows a further schematic illustration of the first particle beam apparatus;

FIG. 2 shows a schematic illustration of a second particle beam apparatus;

FIG. 3 shows a schematic illustration of a third particle beam apparatus;

FIG. 4 shows a schematic illustration of one embodiment of a movement device in the form of an object stage;

FIG. 5 shows a further schematic illustration of the object stage according to FIG. 4; and

FIG. 6 shows a schematic illustration of a sequence of one embodiment of the method according to the system described herein.

### DESCRIPTION OF VARIOUS EMBODIMENTS

The system described herein will now be explained in more detail by way of particle beam apparatuses in the form of an SEM and in the form of a combination apparatus that includes an electron beam column and an ion beam column. Explicit reference is made to the fact that the system described herein may be used in any particle beam apparatus, in particular in any electron beam apparatus and/or any ion beam apparatus.

The figures are not necessarily to scale.

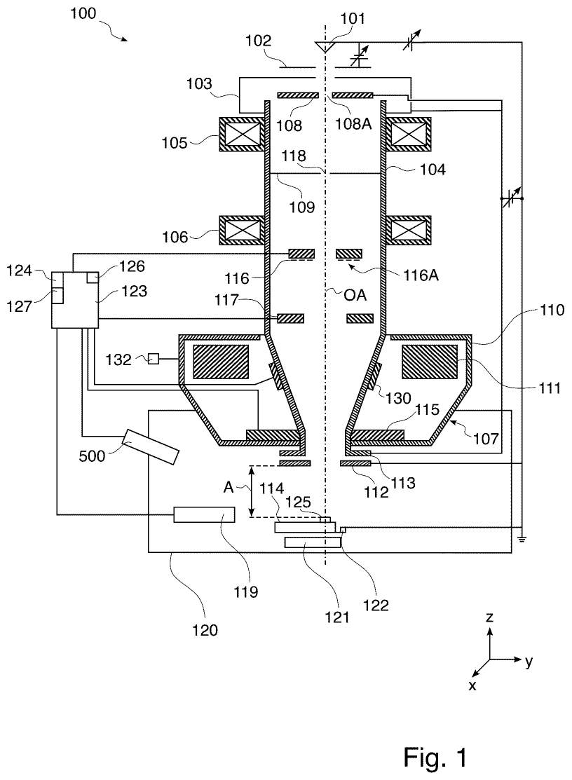

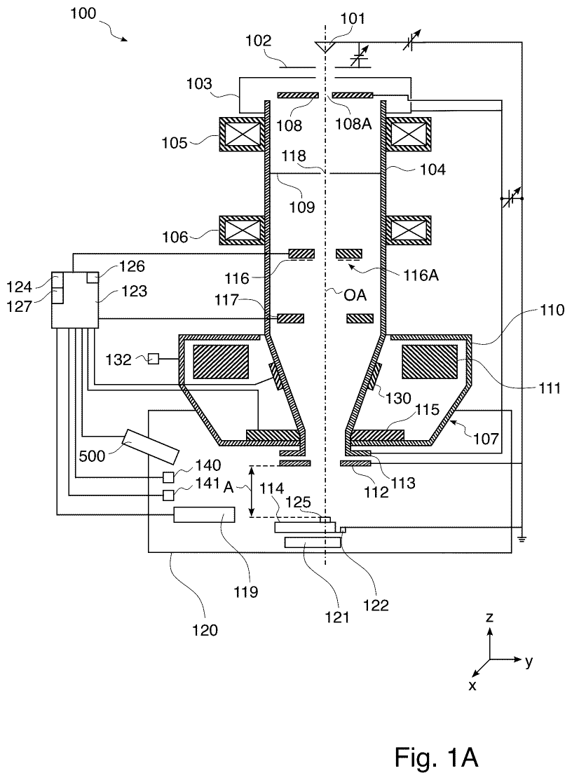

FIG. 1 shows a schematic illustration of an SEM 100. The SEM 100 has a first beam generator in the form of an electron source 101, which is embodied as a cathode. Furthermore, the SEM 100 is provided with an extraction electrode 102 and with an anode 103, which is placed on one end of a beam guiding tube 104 of the SEM 100. By way of example, the electron source 101 is embodied as a thermal field emitter. However, the invention is not restricted to such an electron source 101. On the contrary, any electron source suitable for the invention may be used.

Electrons that emerge from the electron source 101 form a primary electron beam. The electrons are accelerated to anode potential owing to a potential difference between the electron source 101 and the anode 103. In the embodiment illustrated in FIG. 1, the anode potential is 100 V to 35 kV, for example 5 kV to 15 kV, in particular 8 kV, relative to an earth potential of a housing of a sample chamber 120. However, the anode potential could alternatively also be at earth potential.

Two condenser lenses, specifically a first condenser lens 105 and a second condenser lens 106, are arranged on the beam guiding tube 104. As viewed in the direction of a first objective lens 107 proceeding from the electron source 101, the first condenser lens 105 is arranged first in this case, followed by the second condenser lens 106. Explicit reference is made to the fact that further embodiments of the SEM 100 may include only a single condenser lens. A first aperture unit 108 is arranged between the anode 103 and the first condenser lens 105. Together with the anode 103 and the beam guiding tube 104, the first aperture unit 108 is at a high-voltage potential, specifically the potential of the anode 103, or connected to earth. The first aperture unit 108 has numerous first apertures 108A, one of which is illustrated in FIG. 1. For example, two first apertures 108A are present. Each of the numerous first apertures 108A has a different aperture diameter. Using an adjusting mechanism (not illustrated), it is possible to adjust a desired first aperture 108A onto an optical axis OA of the SEM 100. Explicit reference is made to the fact that, in further embodiments, the first aperture unit 108 may be provided only with a single first aperture 108A. An adjusting mechanism might not be provided in the embodiment with a single first aperture 108A. The first aperture unit 108 is then stationary. A stationary second aperture unit 109 is arranged between the first condenser lens 105 and the second condenser lens 106. As an alternative thereto, provision is made for the second aperture unit 109 to be movable.

The first objective lens 107 has pole pieces 110, in which a drilled hole is formed. The beam guiding tube 104 is guided through the drilled hole. A coil 111 is arranged in the pole pieces 110.

An electrostatic retardation device is arranged in a lower region of the beam guiding tube 104. The electrostatic retardation device includes a single electrode 112 and a tube electrode 113. The tube electrode 113 is arranged at an end of the beam guiding tube 104 that faces an object 125 arranged on a movable object holder 114.

The SEM 100 has a first device. By way of example, the first device is understood to be any element able to be arranged movably in and/or on the SEM 100. The element is arranged movably when the element is able to be moved using at least one movement device. Within the meaning of the system described herein, the at least one movement device is embodied such that the at least one movement device is suitable for moving the first device in the SEM 100. By way of example, the first device is arranged on the at least one movement device, where the at least one movement device is embodied in the form of an object stage 122. In the embodiment of the system described herein according to FIG. 1, the first device of the SEM 100 may be embodied as the object 125 and the object holder 114. The object stage 122 may carry out the movement of the first device 114, 125 (in the form of the object holder 114 and of the object 125), for example a translational movement and/or a pivoting movement. The SEM 100 furthermore has at least one second device. By way of example, the at least one second device is understood to be any element able to be arranged in and/or on the SEM 100. In addition or as an alternative, the SEM 100 is understood to be the at least one second device. In the embodiment of the system described herein according to FIG. 1, the at least one second device of the SEM 100 may be embodied as a radiation detector 119. With regard to the radiation detector 119, reference is made to the discussion below.

In this case, the object 125 may denote any element arranged in a sample chamber 120 of the SEM 100.

By way of example, a movement process of the first device 114, 125 is controlled by a control unit 123 of the SEM 100 using the object stage 122. The control unit 123 is in this case embodied such that the control unit 123 is suitable for controlling the SEM 100. By way of example, the control unit 123 is designed to actuate the object stage 122 and/or to actuate a guide device of the SEM 100. With regard to the guide device, reference is made to the discussion below. In other words, the movement process is carried out for example in automated fashion.

In yet other words, the movement device in the form of the object stage 122 may carry out at least one translational movement in at least one spatial direction and/or at least one pivoting movement about at least one axis of rotation. In this case, translational movement is understood to mean a linear movement in which all points of a body experience the same displacement. Pivoting movement is understood to mean a movement in which all points of the body move on circular paths about a common axis (the axis of rotation). In this case, during the pivoting movement, the movement does not have to result in a closed circular path about the common axis.

Together with the beam guiding tube 104, the tube electrode 113 is at the potential of the anode 103, while the single electrode 112 and the object 125 are at a lower potential in relation to the potential of the anode 103. In the present case, the lower potential is the earth potential of the housing of the sample chamber 120. The electrons of the primary electron beam may thereby be decelerated to a desired energy that is desired for examining the object 125.

The object 125 and the single electrode 112 may also be at different potentials and potentials that differ from earth. This makes it possible to adjust the location of the retardation of the primary electron beam in relation to the object 125. For example, aberrations become smaller if the retardation is performed quite close to the object 125.

The SEM 100 furthermore has at least one storage unit 126 in which data are stored and from which data are read out. The SEM 100 furthermore has a processor unit 127. The processor unit 127 is designed to carry out computing operations and/or to execute programs. Program code of a computer program product is loaded into the processor unit 127 and, when executed, controls the SEM 100 such that the method according to the system described herein is carried out. The method according to the system described herein is discussed in more detail below.

The SEM 100 furthermore has a guide device having a first deflection unit 130 and having a second deflection unit. By way of example, a scanning device 115 is embodied as the second deflection unit of the SEM 100. The first deflection unit 130 is arranged on the source side within the first objective lens 107. By contrast, the second deflection unit 115 is arranged on the object side on the beam guiding tube 104 within the first objective lens 107. The first deflection unit 130 and the second deflection unit 115 are crossed beam deflection units. In other words, both the first deflection unit 130 and the second deflection unit 115 are embodied such that the first deflection unit 130 and the second deflection unit 115 deflect the primary electron beam in two directions that are not parallel to one another and are oriented perpendicular to the direction of the optical axis OA of the SEM 100. For example, the first deflection unit 130 and/or the second deflection unit 115 are/is embodied as (a) magnetic deflection unit(s). In particular, the first deflection unit 130 and/or the second deflection unit 115 accordingly each have/has for example four air coils (not illustrated) that are arranged about the optical axis OA of the SEM 100. However, the invention is not restricted to the abovementioned number of air coils. On the contrary, any number of air coils that is suitable for the invention may be used. In addition or as an alternative, provision is made for the first deflection unit 130 and/or the second deflection unit 115 to be embodied as (an) electrostatic deflection unit(s). The first deflection unit 130 and the second deflection unit 115 are then arranged within the beam guiding tube 104. In particular, the first deflection unit 130 and/or the second deflection unit 115 accordingly each have/has for example four electrodes that are arranged about the optical axis OA of the SEM 100 and to which different electrostatic potentials are able to be applied. However, the invention is not restricted to the abovementioned number of electrodes. On the contrary, any number of electrodes that is suitable for the invention may be used. By way of the first deflection unit 130 and the second deflection unit 115, the primary electron beam is deflected and is able to be scanned over the object 125. In the process, the electrons of the primary electron beam interact with the object 125. The interaction gives rise to interaction particles, which are detected. In particular, interaction particles are electrons that are emitted from the surface of the object 125—so-called secondary electrons-or electrons of the primary electron beam that are backscattered—so-called backscattered electrons.

In one embodiment of the SEM 100, the second deflection unit 115 is embodied in the form of the scanning device and designed such that the primary electron beam is able to be guided in targeted fashion onto a region on the surface of the object 125 and over the object 125 (scanning process). In particular, the primary electron beam is guided to any desired number of locations in the region on the surface of the object 125 over the course of the exemplary scanning process.

The SEM 100 has the guide device that guides, shapes, and/or focuses the primary electron beam onto the object 125. The guide device is arranged in and/or on the beam column of the SEM 100 in the form of the beam guiding tube 104. For example, the electrostatic and/or magnetic deflection units mentioned elsewhere herein may be used as the guide device. In particular, the guide device includes the electrostatic and/or magnetic unit that shapes or guides the beam, the stigmator (not illustrated), the first condenser lens 105, the second condenser lens 106, the first objective lens 107, the first deflection unit 130, the second deflection unit 115, the first aperture unit 108 and/or the second aperture unit 109, by way of which the primary electron beam is delimited. In particular, the beam guiding tube 104 of the SEM 100 may also be embodied as the guide device.

A detector arrangement having a first detector 116 and a second detector 117 is arranged in the beam guiding tube 104 for the purpose of detecting the secondary electrons and/or the backscattered electrons. In this case, the first detector 116 is arranged on the source side along the optical axis OA, while the second detector 117 is arranged on the object side along the optical axis OA in the beam guiding tube 104. The first detector 116 and the second detector 117 are arranged offset from one another in the direction of the optical axis OA of the SEM 100. Both the first detector 116 and the second detector 117 have a respective through-opening, through which the primary electron beam is able to pass. The first detector 116 and the second detector 117 are approximately at the potential of the anode 103 and beam guiding tube 104. The optical axis OA of the SEM 100 runs through the respective through-openings.

The second detector 117 is used mainly to detect secondary electrons. Upon emergence from the object 125, the secondary electrons initially have a low kinetic energy and random directions of movement. The secondary electrons are accelerated in the direction of the first objective lens 107 by the strong extraction field that emanates from the tube electrode 113. The secondary electrons enter the first objective lens 107 approximately in a parallel fashion. The beam diameter of the beam of the secondary electrons remains small even in the first objective lens 107. The first objective lens 107 then has a strong effect on the secondary electrons and generates a comparatively short focus of the secondary electrons with sufficiently steep angles to the optical axis OA, and so the secondary electrons diverge significantly from one another downstream of the focus and are incident on the active area of the second detector 117. By contrast, only a small proportion of electrons backscattered at the object 125—that is to say backscattered electrons with a relatively high kinetic energy in comparison with the secondary electrons upon emergence from the object 125—are detected by the second detector 117. The high kinetic energy and the angles of the backscattered electrons to the optical axis OA upon emergence from the object 125 have the effect that a beam waist, that is to say a beam region of minimal diameter, of the backscattered electrons lies in the vicinity of the second detector 117. A large portion of the backscattered electrons pass through the through-opening of the second detector 117. Therefore, the first detector 116 substantially serves to detect the backscattered electrons.

In a further embodiment of the SEM 100, the first detector 116 may be additionally embodied with an opposing field grid 116A. The opposing field grid 116A is arranged on that side of the first detector 116 that is directed towards the object 125. With respect to the potential of the beam guiding tube 104, the opposing field grid 116A has a negative potential such that only backscattered electrons with a high kinetic energy pass through the opposing field grid 116A to the first detector 116. In addition or as an alternative, the second detector 117 has a further opposing field grid, which is embodied analogously to the abovementioned opposing field grid 116A of the first detector 116 and has an analogous function.

Furthermore, in the sample chamber 120, the SEM 100 has a chamber detector 500, for example an Everhart-Thornley detector or an ion detector, which has a detection surface that is coated with metal and blocks light.

The detection signals generated by the first detector 116, the second detector 117 and the chamber detector 500 are used to generate an image or images of the surface of the object 125.

Explicit reference is made to the fact that the apertures of the first aperture unit 108 and of the second aperture unit 109 and also the through-openings of the first detector 116 and of the second detector 117 are illustrated in exaggerated fashion. The through-openings of the first detector 116 and of the second detector 117 have an extent perpendicular to the optical axis OA in the range of 0.5 mm to 5 mm. For example, the through-openings are circular and have a diameter in the range of 1 mm to 3 mm perpendicular to the optical axis OA.

The second aperture unit 109 is designed as a pinhole aperture unit in the embodiment illustrated in FIG. 1 and is provided with a second aperture 118 for the passage of the primary electron beam, which aperture has an extent in the range of 5 μm to 500 μm, for example 35 μm. As an alternative, in a further embodiment, provision is made for the second aperture unit 109 to be provided with a plurality of apertures, which are able to be displaced mechanically with respect to the primary electron beam or which are able to be reached by the primary electron beam using electrical and/or magnetic deflection units. The second aperture unit 109 is embodied as a pressure stage aperture unit. The pressure stage aperture unit separates a first region, in which the electron source 101 is arranged and in which there is an ultra-high vacuum (10⁻⁷ hPa to 10⁻¹² hPa), from a second region, which has a high vacuum (10⁻³ hPa to 10⁻⁷ hPa). The second region is the intermediate pressure region of the beam guiding tube 104 leading to the sample chamber 120.

The sample chamber 120 is under vacuum. In order to generate the vacuum, a pump (not illustrated) is arranged on the sample chamber 120. In the embodiment illustrated in FIG. 1, the sample chamber 120 is operated in a first pressure range or in a second pressure range. The first pressure range includes only pressures less than or equal to 10⁻³ hPa, and the second pressure range includes only pressures greater than 10⁻³ hPa. The sample chamber 120 is vacuum-sealed in order to ensure the indicated pressure ranges.

The object holder 114 is arranged on the object stage 122. The object stage 122 is embodied so as to be movable in three directions arranged perpendicular to one another, specifically in an x-direction (first stage axis), in a y-direction (second stage axis) and in a z-direction (third stage axis). Moreover, the object stage 122 is able to be rotated about two axes of rotation (axes of rotation of the stage) that are arranged perpendicular to one another. The invention is not restricted to the object stage 122 described above. On the contrary, the object stage 122 may have further translation axes and axes of rotation along which or about which the object stage 122 is able to move. In the embodiment of the system described herein according to FIG. 1, the abovementioned at least one movement device is embodied as the object stage 122.

The SEM 100 furthermore has a third detector 121, which is arranged in the sample chamber 120. More precisely, the third detector 121 is arranged downstream of the object stage 122, as viewed from the electron source 101 along the optical axis OA. The object stage 122, and hence the object holder 114, may be rotated such that the primary electron beam is able to radiate through the object 125 arranged on the object holder 114. When the primary electron beam passes through the object 125 to be examined, the electrons of the primary electron beam interact with the material of the object 125 to be examined. The electrons passing through the object 125 to be examined are detected by the third detector 121.

Arranged on the sample chamber 120 is the radiation detector 119, which is used to detect interaction radiation, for example x-ray radiation and/or cathodoluminescence, generated when the primary electron beam is incident on the object 125. The radiation detector 119, the first detector 116, the second detector 117 and the chamber detector 500 are connected to the control unit 123, which has a display unit 124. The third detector 121, too, is connected to the control unit 123, which is not illustrated for reasons of clarity. The control unit 123 processes detection signals generated by the first detector 116, the second detector 117, the radiation detector 119, the third detector 121 and/or the chamber detector 500 and displays the detection signals in the form of images on the display unit 124.

The control unit 123 is connected to the guide device in the form of the first deflection unit 130 and the second deflection unit 115. Moreover, the control unit 123 is connected to further units of the SEM 100, which is not illustrated in more detail for reasons of clarity.

In the SEM 100, it is possible to adjust a distance A using the control unit 123 of the SEM 100. The distance A is given either (a) by an object distance between an outer boundary of the first objective lens 107 of the SEM 100 and the object 125 or (b) by a focal plane distance between the outer boundary of the first objective lens 107 of the SEM 100 and a focal plane of the first objective lens 107. The abovementioned distance A according to case (a) or case (b) is also referred to as working distance. For example, the distance A in case (a) is adjusted by moving the object stage 122 and/or moving the first objective lens 107 using a lens movement device 132. For example, the distance A in case (b) is adjusted by varying an excitation of the first objective lens 107 along the optical axis OA of the SEM 100.

FIG. 1A shows a further schematic illustration of the SEM 100. The further schematic illustration of the SEM 100 is based on FIG. 1. Reference is made to FIG. 1 and, initially, to the explanations provided above, which also apply in this case.

As a departure from FIG. 1, according to FIG. 1A, a detector 140 that records structure data and a sensor 141 that records structure data are embodied on the SEM 100. By way of example, the detector 140 that records structure data and/or the sensor 141 that records structure data is designed to capture at least one first surface arrangement of the first device and/or at least one second surface arrangement of the at least one second device. By way of example, the detector 140 that records structure data is embodied as an optical camera. By way of example, the sensor 141 that records structure data is embodied as a light sensor, a LIDAR sensor and/or an ultrasonic sensor.

In one embodiment of the SEM 100, provision is made, in addition or as an alternative, for the first device and/or the at least one second device to be embodied as at least one of the following units: as the object 125, as the object stage 122, as the object holder 114, as a micromanipulator, as the sample chamber 120, as a lock, as a light source, as the beam column (for example in the form of the beam guiding tube 104), as a capture device in the form of at least one of the abovementioned detectors 116, 117, 119, 121, 140, 500, as the capture device in the form of the sensor 141, as a gas injection system, as a charge compensation device, as a camera, as a lock bar, as a gripper, as a scanning system (in the form of the first condenser lens 105 and/or the second condenser lens 106 and/or the first objective lens 107 and/or the second deflection unit 115 and/or the first deflection unit 130), as an electrode (in the form of the single electrode 112 and/or the tube electrode 113), as a cable, as a hose, as a scanning force microscope, as a microtome, as a plasma cleaner, as a Faraday cup, as a aperture unit (in the form of the first aperture unit 108 and/or the second aperture unit 109), as an objective cap, as at least part of the beam column 104, and as the SEM 100. In this case, the capture device may be for example the detector 140 that records structure data and/or the sensor 141 that records structure data. In addition or as an alternative, the capture device may be any of the abovementioned detectors 116, 117, 119, 121, 500 arranged in and/or on the SEM 100.

In other words, any element within the SEM 100 and/or the SEM 100 itself that is suitable within the meaning of the system described herein may be used as the first device and/or as the at least one second device. An element within the meaning of the system described herein is suitable as the first device if the element is able to be arranged movably within the SEM 100. By way of example, the element within the meaning of the system described herein is suitable as a first device if the element is designed such that the element moves relative to another element using the object stage 122. In this case, the movement may be automated, for example by virtue of the movement being carried out using the control unit 123. In addition or as an alternative, the movement may be manual, for example if the movement is carried out through manual actuation of the user of the SEM 100. An element within the meaning of the system described herein is suitable as the at least one second device if the element is able to be arranged within the SEM 100 and/or is the SEM 100. By way of example, the at least one second device may also be arranged only partially within the SEM 100, for example if the at least one second device is embodied as the lock. In particular, an element within the meaning of the system described herein is suitable as the at least one second device if, owing to the movement of the first device, the first device and the at least one second device may collide and/or be at the shortest distance that falls below the predefinable minimum distance.

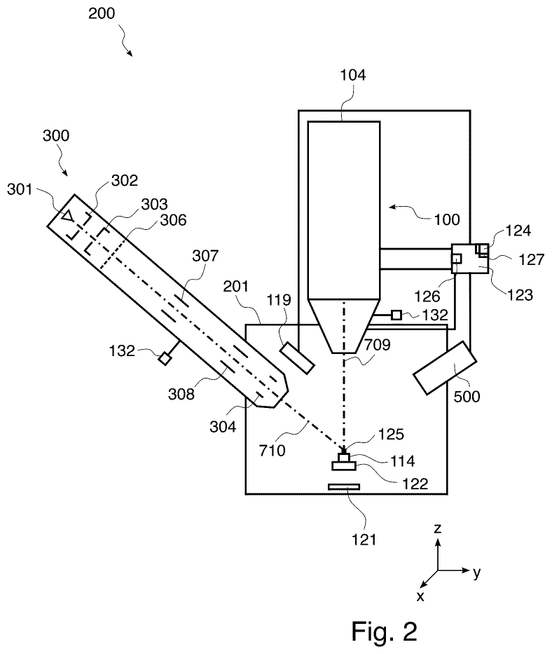

FIG. 2 shows a particle beam apparatus in the form of a combination apparatus 200.

The combination apparatus 200 has two particle beam columns. Firstly, the combination apparatus 200 is provided with the SEM 100, as already illustrated in FIG. 1, albeit without the sample chamber 120. On the contrary, the SEM 100 is arranged on a sample chamber 201. The sample chamber 201 is under vacuum. In order to generate the vacuum, a pump (not illustrated) is arranged on the sample chamber 201. In the embodiment illustrated in FIG. 2, the sample chamber 201 is operated in a first pressure range or in a second pressure range. The first pressure range includes only pressures less than or equal to 10⁻³ hPa, and the second pressure range includes only pressures greater than 10⁻³ hPa. The sample chamber 201 is vacuum-sealed in order to ensure the indicated pressure ranges.

The third detector 121 is arranged in the sample chamber 201.

The SEM 100 serves to generate a first particle beam, specifically the primary electron beam described above, and has the optical axis mentioned above, which is provided with reference sign 709 in FIG. 2 and also referred to as a first beam axis below. Secondly, the combination apparatus 200 is provided with an ion beam apparatus 300, which is likewise arranged on the sample chamber 201. The ion beam apparatus 300 likewise has an optical axis, which is provided with a reference sign 710 in FIG. 2 and is also referred to as second beam axis below.

The SEM 100 is for example arranged vertically in relation to the sample chamber 201. By contrast, the ion beam apparatus 300 is arranged in a manner inclined by an angle of for example approximately 0° to 90° in relation to the SEM 100. For example, an arrangement of approximately 50° is illustrated in FIG. 2. The ion beam apparatus 300 has a second beam generator in the form of an ion beam generator 301. Ions that form a second particle beam in the form of an ion beam are generated by the ion beam generator 301. The ions are accelerated by way of an extraction electrode 302 at a predefinable potential. The second particle beam then passes through an ion optical unit of the ion beam apparatus 300, the ion optical unit having a condenser lens 303 and a second objective lens 304. The second objective lens 304 ultimately generates an ion probe, which is focused onto the object 125 arranged on an object holder 114. The object holder 114 is arranged on an object stage 122.

An adjustable or selectable aperture unit 306, a first electrode arrangement 307 and a second electrode arrangement 308 are arranged above the second objective lens 304 (that is to say in the direction of the ion beam generator 301), with the first electrode arrangement 307 and the second electrode arrangement 308 being embodied as scanning electrodes. The second particle beam is scanned over the surface of the object 125 by way of the first electrode arrangement 307 and the second electrode arrangement 308, with the first electrode arrangement 307 acting in a first direction and the second electrode arrangement 308 acting in a second direction opposite the first direction. Hence, the scanning is carried out for example in a first direction. The scanning in a second direction perpendicular thereto is effected by further electrodes (not illustrated), which are rotated by 90°, on the first electrode arrangement 307 and on the second electrode arrangement 308.

As explained above, the object holder 114 is arranged on the object stage 122 or forms the object stage 122. In the embodiment shown in FIG. 2, too, the object stage 122 is embodied so as to be movable in three directions arranged perpendicular to one another, specifically in an x-direction (first stage axis), in a y-direction (second stage axis) and in a z-direction (third stage axis). Moreover, the object stage 122 is able to be rotated about two axes of rotation (axes of rotation of the stage) that are arranged perpendicular to one another.

The distances illustrated in FIG. 2 between the individual units of the combination apparatus 200 are illustrated in exaggerated fashion in order to better illustrate the individual units of the combination apparatus 200.

The radiation detector 119 used to detect interaction radiation, for example x-ray radiation and/or cathodoluminescence, is arranged in the sample chamber 201. The radiation detector 119 is connected to the control unit 123, which has the display unit 124 and the processor unit 127. In addition or as an alternative, a further detector in the form of the chamber detector 500, in particular that detects secondary electrons, may be arranged in the sample chamber 201. The further detector is likewise connected to the control unit 123. The control unit 123 processes detection signals generated by the first detector 116 (not illustrated in FIG. 2), the second detector 117 (not illustrated in FIG. 2), the third detector 121, the radiation detector 119 and/or the chamber detector 500 and displays the resulting detection signals in the form of numerical values, diagrams, images and/or analyses on the display unit 124.

The control unit 123 furthermore has the storage unit 126, in which data are stored and from which data are read out. The control unit 123 furthermore has the processor unit 127. The processor unit 127 is designed to carry out computing operations and/or to execute programs. Program code of a computer program product is loaded into the processor unit 127 and, when executed, controls the combination apparatus 200 such that the method according to the system described herein is carried out. The method according to the system described herein is discussed in more detail below.

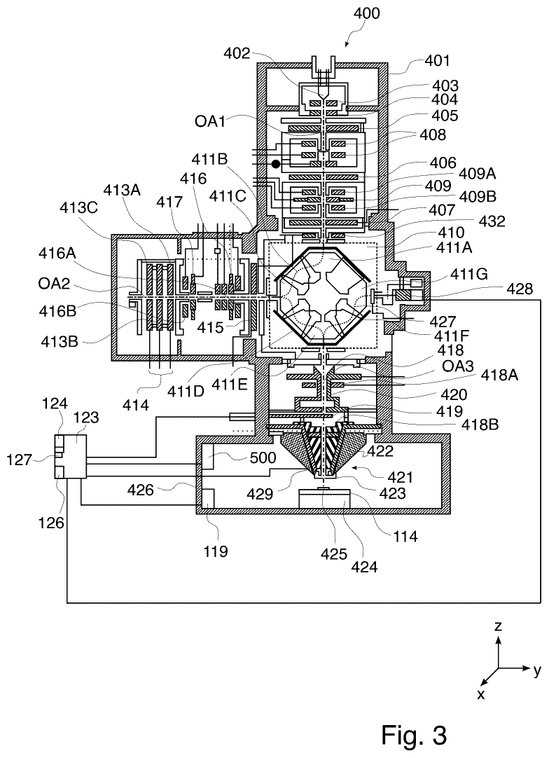

FIG. 3 is a schematic illustration of a further embodiment of a particle beam apparatus according to the system described herein. The embodiment of FIG. 3 of the particle beam apparatus is provided with the reference sign 400 and includes a mirror corrector that corrects chromatic and/or spherical aberration, for example. The particle beam apparatus 400 includes a particle beam column 401, which is embodied as an electron beam column and which substantially corresponds to an electron beam column of a corrected SEM. However, the particle beam apparatus 400 is not restricted to an SEM with a mirror corrector. On the contrary, the particle beam apparatus may include any type of corrector units that are suitable as corrector units within the meaning of the system described herein.

The particle beam column 401 includes a particle beam generator in the form of an electron source 402 (cathode), an extraction electrode 403 and an anode 404. For example, the electron source 402 is embodied as a thermal field emitter. Electrons emerging from the electron source 402 are accelerated to the anode 404 owing to a potential difference between the electron source 402 and the anode 404. Accordingly, a particle beam in the form of an electron beam is formed along a first optical axis OA1.

The particle beam is guided along a beam path that corresponds to the first optical axis OA1 after the particle beam has emerged from the electron source 402. A first electrostatic lens 405, a second electrostatic lens 406 and a third electrostatic lens 407 are used to guide the particle beam.

Furthermore, the particle beam is adjusted along the beam path using a deflection device. The deflection device in the embodiment of FIG. 3 includes a source adjusting unit having two magnetic deflection units 408 arranged along the first optical axis OA1. Moreover, the particle beam apparatus 400 includes electrostatic beam deflection units. A first electrostatic beam deflection unit 409, which is also embodied as a quadrupole in a further embodiment, is arranged between the second electrostatic lens 406 and the third electrostatic lens 407. The first electrostatic beam deflection unit 409 is likewise arranged downstream of the magnetic deflection units 408. A first multi-pole unit 409A in the form of a first magnetic deflection unit is arranged on one side of the first electrostatic beam deflection unit 409. Moreover, a second multi-pole unit 409B in the form of a second magnetic deflection unit is arranged on the other side of the first electrostatic beam deflection unit 409. The first electrostatic beam deflection unit 409, the first multi-pole unit 409A and the second multi-pole unit 409B are adjusted for the purpose of adjusting the particle beam in relation to the axis of the third electrostatic lens 407 and the entrance window of a beam deflection device 410. The first electrostatic beam deflection unit 409, the first multi-pole unit 409A and the second multi-pole unit 409B may interact like a Wien filter. A further magnetic deflection unit 432 is arranged at the entrance to the beam deflection device 410.

The beam deflection device 410 is used as a particle beam deflector, which deflects the particle beam in a specific manner. The beam deflection device 410 includes a plurality of magnetic sectors, specifically a first magnetic sector 411A, a second magnetic sector 411B, a third magnetic sector 411C, a fourth magnetic sector 411D, a fifth magnetic sector 411E, a sixth magnetic sector 411F and a seventh magnetic sector 411G. The particle beam enters the beam deflection device 410 along the first optical axis OA1 and is deflected by the beam deflection device 410 in the direction of a second optical axis OA2. The beam is deflected by an angle of 30° to 120° by way of the first magnetic sector 411A, by way of the second magnetic sector 411B and by way of the third magnetic sector 411C.

The second optical axis OA2 is oriented at the same angle with respect to the first optical axis OA1. The beam deflection device 410 also deflects the particle beam that is guided along the second optical axis OA2, to be precise in the direction of a third optical axis OA3. The beam deflection is provided by the third magnetic sector 411C, the fourth magnetic sector 411D and the fifth magnetic sector 411E. In the embodiment in FIG. 3, the deflection with respect to the second optical axis OA2 and with respect to the third optical axis OA3 is provided by deflection of the particle beam at an angle of 90°. Hence, the third optical axis OA3 runs coaxially with the first optical axis OA1. However, reference is made to the fact that the particle beam apparatus 400 according to the system described herein is not restricted to deflection angles of 90°. On the contrary, any suitable deflection angle by the beam deflection device 410 may be chosen, for example 70° or 110°, with the result that the first optical axis OA1 does not run coaxially with respect to the third optical axis OA3. With regard to further details of the beam deflection device 410, reference is made to WO 2002/067286 A2.

After the particle beam has been deflected by the first magnetic sector 411A, the second magnetic sector 411B and the third magnetic sector 411C, the particle beam is guided along the second optical axis OA2. The particle beam is guided to an electrostatic mirror 414 and travels on a path to the electrostatic mirror 414 along a fourth electrostatic lens 415, a third multi-pole unit 416A in the form of a magnetic deflection unit, a second electrostatic beam deflection unit 416, a third electrostatic beam deflection unit 417 and a fourth multi-pole unit 416B in the form of a magnetic deflection unit. The electrostatic mirror 414 includes a first mirror electrode 413A, a second mirror electrode 413B and a third mirror electrode 413C. Electrons of the particle beam that are reflected back at the electrostatic mirror 414 once again travel along the second optical axis OA2 and re-enter the beam deflection device 410. Then, the electrons are deflected to the third optical axis OA3 by the third magnetic sector 411C, the fourth magnetic sector 411D and the fifth magnetic sector 411E.

The electrons of the particle beam emerge from the beam deflection device 410 and are guided along the third optical axis OA3 to an object 425 that is intended to be examined and is arranged in an object holder 114. On the path to the object 425, the particle beam is guided to a fifth electrostatic lens 418, a beam guiding tube 420, a fifth multi-pole unit 418A, a sixth multi-pole unit 418B and an objective lens 421. The fifth electrostatic lens 418 is an electrostatic immersion lens. By way of the fifth electrostatic lens 418, the particle beam is decelerated or accelerated to an electrical potential of the beam guiding tube 420.

By way of the objective lens 421, the particle beam is focused into a focal plane in which the object 425 is arranged. The object holder 114 is arranged on a movable object stage 424 or forms the object stage 424. The movable object stage 424 is arranged in a sample chamber 426 of the particle beam apparatus 400. The object stage 424 is embodied so as to be movable in three directions arranged perpendicular to one another, specifically in an x-direction (first stage axis), in a y-direction (second stage axis) and in a z-direction (third stage axis). Moreover, the object stage 424 is able to be rotated about two axes of rotation (axes of rotation of the stage) that are arranged perpendicular to one another.

The sample chamber 426 is under vacuum. In order to generate the vacuum, a pump (not illustrated) is arranged on the sample chamber 426. In the embodiment illustrated in FIG. 3, the sample chamber 426 is operated in a first pressure range or in a second pressure range. The first pressure range includes only pressures less than or equal to 10⁻³ hPa, and the second pressure range includes only pressures greater than 10⁻³ hPa. The sample chamber 426 is vacuum-sealed in order to ensure the indicated pressure ranges.

The objective lens 421 may be embodied as a combination of a magnetic lens 422 and a sixth electrostatic lens 423. The end of the beam guiding tube 420 may furthermore be an electrode of an electrostatic lens. After emerging from the beam guiding tube 420, particles of the particle beam are decelerated to a potential of the object 425. The objective lens 421 is not restricted to a combination of the magnetic lens 422 and the sixth electrostatic lens 423. On the contrary, the objective lens 421 may assume any suitable form. For example, the objective lens 421 may also be embodied as a purely magnetic lens or as a purely electrostatic lens.

The particle beam that is focused onto the object 425 interacts with the object 425. Interaction particles are generated. In particular, secondary electrons are emitted from the object 425 or backscattered electrons are backscattered at the object 425. The secondary electrons or the backscattered electrons are accelerated again and guided into the beam guiding tube 420 along the third optical axis OA3. In particular, the trajectories of the secondary electrons and of the backscattered electrons travel on the route of the beam path of the particle beam in the opposite direction to the particle beam.

The particle beam apparatus 400 includes a first analysis detector 419, which is arranged between the beam deflection device 410 and the objective lens 421 along the beam path. Secondary electrons travelling in directions oriented at a large angle with respect to the third optical axis OA3 are detected by the first analysis detector 419. Backscattered electrons and secondary electrons that are at a small axial distance with respect to the third optical axis OA3 at the location of the first analysis detector 419 enter the beam deflection device 410 and are deflected along a detection beam path 427 to a second analysis detector 428 by the fifth magnetic sector 411E, the sixth magnetic sector 411F and the seventh magnetic sector 411G. For example, the deflection angle is 90° or 110°.

The first analysis detector 419 generates detection signals that are largely generated by emitted secondary electrons. The detection signals generated by the first analysis detector 419 are guided to the control unit 123 and are used to obtain information about the properties of the region of interaction of the focused particle beam with the object 425. In particular, the focused particle beam is scanned over the object 425 using a scanning device 429. By way of the detection signals generated by the first analysis detector 419, an image of the scanned region of the object 425 is then able to be generated and displayed on a presentation unit. The presentation unit is for example the display unit 124 that is arranged on the control unit 123. The control unit 123 moreover has the processor unit 127.

The second analysis detector 428 is also connected to the control unit 123. Detection signals from the second analysis detector 428 are guided to the control unit 123 and used to generate an image of the scanned region of the object 425 and to display the image on a presentation unit. The presentation unit is for example the display unit 124 that is arranged on the control unit 123.

The radiation detector 119 used to detect interaction radiation, for example x-ray radiation and/or cathodoluminescence, is arranged on or in the sample chamber 426. The radiation detector 119 is connected to the control unit 123, which has the display unit 124. The control unit 123 processes detection signals from the radiation detector 119 and displays the detection signals in the form of analyses on the display unit 124.

The control unit 123 furthermore has the storage unit 126, in which data are stored and from which data are read out. In other words, the storage unit 126 is suitable for storing data and for retrieving data. The control unit 123 furthermore has the processor unit 127. The processor unit 127 of the particle beam apparatus 400 is designed to carry out computing operations and/or to execute programs. Program code of a computer program product is loaded into the processor unit 127 and, when executed, controls the particle beam apparatus 400 such that the method according to the system described herein is carried out. The method according to the system described herein is discussed in more detail below.

Moreover, the particle beam apparatus 400 has the chamber detector 500, which is connected to the control unit 123.

In the case of the particle beam apparatus 400, the particle beam may be rotated (for example tilted) in relation to the object 425, for example using the fifth multi-pole unit 418A and the sixth multi-pole unit 418B. In addition or as an alternative, the particle beam may be rotated (for example tilted) in relation to the object 425, for example using the first multi-pole unit 409A and the second multi-pole unit 409B.

As explained above, any element within the particle beam apparatus and/or the particle beam apparatus itself that is suitable within the meaning of the system described herein may be embodied as the first device and/or as the at least one second device. By way of example, in addition or as an alternative to the stated exemplary embodiment of the at least one second device as a radiation detector 119, the at least one second device may be embodied as at least one of the following units: as the SEM 100, as the beam guiding tube 104, as the first condenser lens 105, as the second condenser lens 106, as the first objective lens 107, as the first aperture unit 108, as the second aperture unit 109, as the single electrode 112, as the tube electrode 113, as the object holder 114, as the second deflection unit 115, as the first detector 116, as the second detector 117, as the radiation detector 119, as the sample chamber 120, as the third detector 121, as the object stage 122, as the object 125, as the first deflection unit 130, as the detector 140 that records structure data, as the sensor 141 that records structure data, as the combination apparatus 200, as the sample chamber 201, as the ion beam apparatus 300, as the condenser lens 303, as the second objective lens 304, as the adjustable or selectable aperture unit 306, as the first electrode arrangement 307, as the second electrode arrangement 308, as the particle beam apparatus 400 including a corrector unit, as the first electrostatic lens 405, as the second electrostatic lens 406, as the third electrostatic lens 407, as the magnetic deflection unit 408, as the first electrostatic beam deflection unit 409, as the first multi-pole unit 409A, as the second multi-pole unit 409B, as the beam deflection device 410, as the first magnetic sector 411A, as the second magnetic sector 411B, as the third magnetic sector 411C, as the fourth magnetic sector 411D, as the fifth magnetic sector 411E, as the sixth magnetic sector 411F, as the seventh magnetic sector 411G, as the first mirror electrode 413A, as the second mirror electrode 413B, as the third mirror electrode 413C, as the electrostatic mirror 414, as the fourth electrostatic lens 415, as the second electrostatic beam deflection unit 416, as the third multi-pole unit 416A, as the fourth multi-pole unit 416B, as the third electrostatic beam deflection unit 417, as the fifth electrostatic lens 418, as the fifth multi-pole unit 418A, as the sixth multi-pole unit 418B, as the first analysis detector 419, as the beam guiding tube 420, as the objective lens 421, as the magnetic lens 422, as the sixth electrostatic lens 423, as the object stage 424, as the object 425, as the sample chamber 426, as the second analysis detector 428, as the scanning device 429, as the further magnetic deflection unit 432 and as the chamber detector 500.

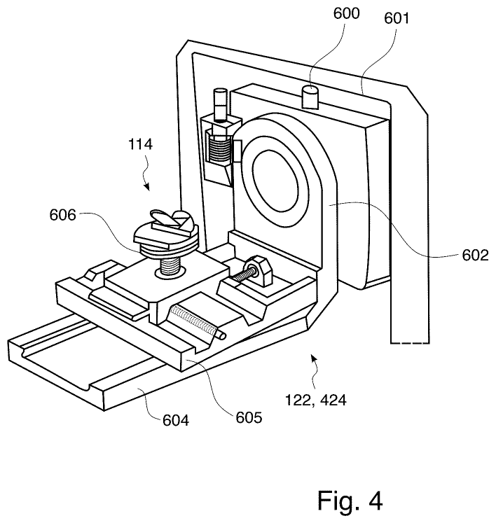

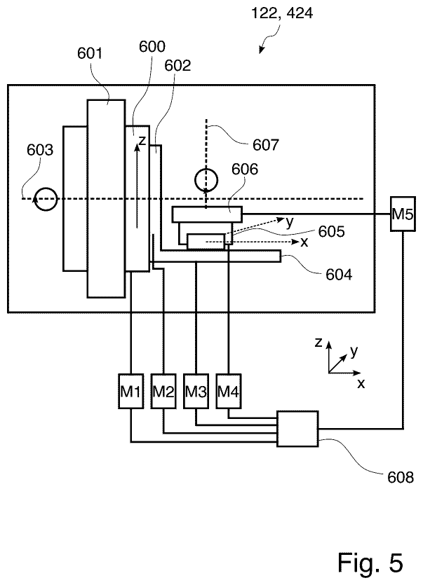

The object stage 122, 424 of the particle beam apparatuses 100, 200 and 400 explained above is discussed in greater detail below. The object stage 122, 424 is embodied as a movable object carrier in the form of an object stage, which is illustrated schematically in FIGS. 4 and 5. Reference is made to the fact that the invention is not restricted to the object stage 122, 424 described here. On the contrary, the invention may include any movable object stage suitable for the invention.

The object holder 114 is arranged on the object stage 122, 424. The object stage 122, 424 has movement elements that ensure a movement of the object stage 122, 424 such that a region of interest on the object 125, 425 is able to be examined, for example by way of a particle beam. The movement elements are illustrated schematically in FIGS. 4 and 5 and are explained below.

The object stage 122, 424 has a first movement element 600, which for example is arranged on a housing 601 of the sample chamber 120, 201 or 426, in which in turn the object stage 122, 424 is arranged. The first movement element 600 enables a movement of the object stage 122, 424 along the z-axis (third stage axis). Furthermore, a second movement element 602 is provided. The second movement element 602 enables a rotation of the object stage 122, 424 about a first axis of rotation 603 of the stage, which is also referred to as a tilt axis. This second movement element 602 serves to tilt the object 125, 425 about the first axis of rotation 603 of the stage, where the object 125, 425 is arranged on the object holder 114.

Arranged on the second movement element 602, in turn, is a third movement element 604, which is embodied as a guide for a slide and ensures that the object stage 122, 424 is movable in the x-direction (first stage axis). The abovementioned slide is in turn a further movement element, specifically a fourth movement element 605. The fourth movement element 605 is embodied such that the object stage 122, 424 is movable in the y-direction (second stage axis). For this purpose, the fourth movement element 605 has a guide in which a further slide is guided, the object holder 114 in turn being arranged on the latter.

The object holder 114 is in turn embodied with a fifth movement element 606, which enables a rotation of the object holder 114 about a second axis of rotation 607 of the stage. The second axis of rotation 607 of the stage is oriented perpendicular to the first axis of rotation 603 of the stage.

On account of the above-described arrangement, the object stage 122, 424 of the embodiment discussed here has the following kinematic chain: First movement element 600 (movement along the z-axis)—second movement element 602 (rotation about the first axis of rotation 603 of the stage)—third movement element 604 (movement along the x-axis)—fourth movement element 605 (movement along the y-axis)—fifth movement element 606 (rotation about the second axis of rotation 607 of the stage). In addition or as an alternative, other kinematic chains may also be realized.

In a further embodiment (not illustrated), provision is made for further movement elements to be arranged on the object stage 122, 424 such that movements along further translational axes and/or about further axes of rotation are made possible.

As is evident from FIG. 5, each of the abovementioned movement elements is connected to a drive unit M1 to M5 in the form of a motor. In this regard, the first movement element 600 is connected to a first drive unit M1 and is driven owing to a driving force that is provided by the first drive unit M1. The second movement element 602 is connected to a second drive unit M2, which drives the second movement element 602. The third movement element 604 is connected in turn to a third drive unit M3. The third drive unit M3 provides a driving force that drives the third movement element 604. The fourth movement element 605 is connected to a fourth drive unit M4, with the fourth drive unit M4 driving the fourth movement element 605. Furthermore, the fifth movement element 606 is connected to a fifth drive unit M5. The fifth drive unit M5 provides a driving force that drives the fifth movement element 606.

The abovementioned drive units M1 to M5 may be embodied as stepper motors, for example, and are controlled by a drive control unit 608 and are each supplied with a supply current by the drive control unit 608 (cf. FIG. 5). Explicit reference is made to the fact that the invention is not restricted to the movement of the object stage 122, 424 by way of stepper motors. On the contrary, any drive units suitable within the meaning of the invention as drive units, for example brushless motors, may be used as drive units.

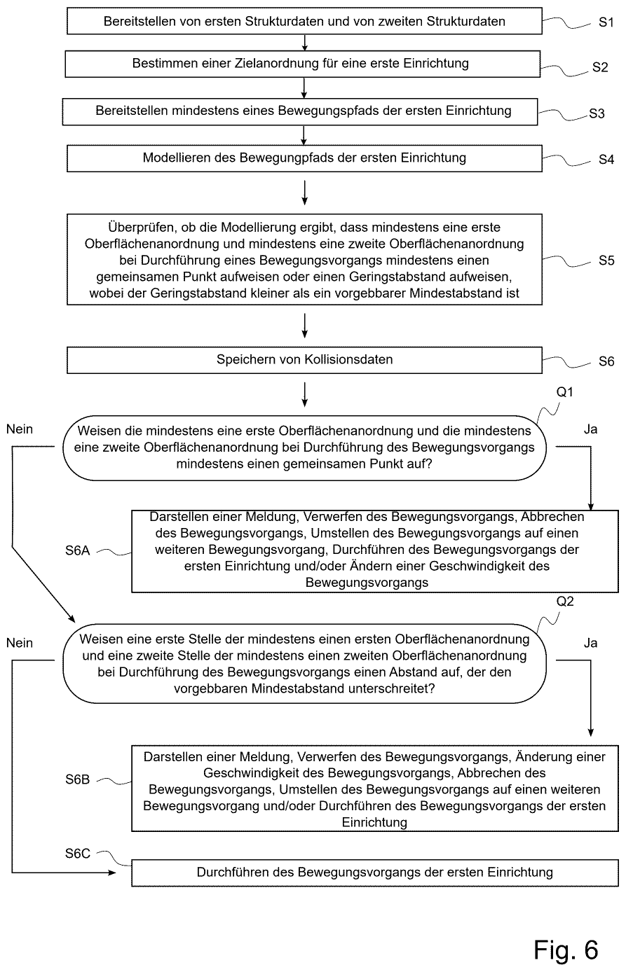

Embodiments of the method according to the system described herein for operating a particle beam apparatus 100, 200, 400 that images, processes, and/or analyses the object 125, 425 are explained in more detail below with respect to the SEM 100 according to FIG. 1. FIG. 6 shows a schematic illustration of a sequence of an embodiment of the method according to the system described herein, which is carried out by the SEM 100 in accordance with FIG. 1. The statements below are applicable, mutatis mutandis, with respect to carrying out an embodiment of the method according to the system described herein in the case of the further particle beam apparatuses 200 and 400 mentioned above. Below, the first device is embodied by way of example as the object holder 114 with the object 125, and the at least one second device is embodied as the radiation detector 119. The statements above apply analogously here with regard to the first device 114, 125 (that is to say in the form of the object holder 114 and the object 125) and the at least one second device 119 (that is to say in the form of the radiation detector 119).

The method according to the system described herein serves for operating the SEM 100 that images, processes, and/or analyses the object 125. In this case, the object 125 may denote any element arranged in the sample chamber 120 of the SEM 100. In other words, any element arranged in the sample chamber 120 of the SEM 100 may be embodied as the object 125.

Inter alia, in the method according to the system described herein, (A) first structure data and second structure data are provided; (B) a target arrangement for the first device 114, 125 is determined; (C) at least one movement path of the first device 114, 125 to reach the target arrangement for the first device 114, 125 is provided; (D) the at least one movement path of the first device 114, 125 within the SEM 100 is modelled; (E) a check is carried out to determine whether the modelling of the movement path has the result that the at least one first surface arrangement of the first device 114, 125 and the at least one second surface arrangement of the at least one second device 119, when carrying out the movement process, (i) have at least one common point or (ii) are at a shortest distance, where the shortest distance is smaller than a predefinable minimum distance, but do not have a common point; (F) optionally, a result of the check is stored in the storage unit 126 as collision data; and (G) depending on a result of the check, a message is displayed and/or a movement process is discarded and/or a speed of the movement process is changed and/or the movement process is aborted and/or the movement process is switched to a further movement process and/or the movement process of the first device 114, 125 along the provided movement path is carried out using the object stage 122.

In a method step S1 of the method according to the system described herein, first structure data and second structure data are provided. The first structure data and the second structure data are discussed in more detail below.

The first structure data includes information about at least one first surface arrangement of the first device 114, 125 within the SEM 100. In other words, by way of example, the at least one first surface arrangement of the first device 114, 125 may be described by the first structure data. The second structure data includes information about at least one second surface arrangement of the at least one second device 119 within the SEM 100. In other words, by way of example, the at least one second surface arrangement of the at least one second device 119 may be described by the second structure data.

By way of example, provision is made for the first surface arrangement to have a first space of finite extent, which partially or completely surrounds the first device 114, 125. In other words, the first space of finite extent delimits the first surface arrangement. Proceeding from the first device 114, 125, the first space of finite extent has for example an extent of up to 100 mm, of up to 50 mm, of up to 20 mm, of up to 10 mm, of up to 1 mm, of up to 500 μm, of up to 300 μm, of up to 100 μm or of up to 10 μm. However, the invention is not restricted to such extents. On the contrary, the extent of the first space of finite extent may have any value suitable for the invention. In particular, the extent of the first space of finite extent is variable. By way of example, the extent of the first space of finite extent is dependent on the speed of movement of the first device 114, 125 and/or of the at least one second device 119. In addition or as an alternative, the extent of the first space of finite extent is dependent on the distance between the first device 114, 125 and the at least one second device 119. Provision is made in particular for the extent of the first space of finite extent to become larger as the distance between the first device 114, 125 and the at least one second device 119 increases, and for the extent of the first space of finite extent to become smaller as the distance between the first device 114, 125 and the at least one second device 119 decreases. In addition or as an alternative, provision is made for the extent of the first space of finite extent to become larger as the speed of movement of the first device 114, 125 and/or of the at least one second device 119 increases, and for the extent of the first space of finite extent to become smaller as the speed of movement of the first device 114, 125 and/or of the at least one second device 119 decreases.

Provision is furthermore made for example for the second surface arrangement to have a second space of finite extent, which partially or completely surrounds the at least one second device 119. In other words, the second space of finite extent delimits the second surface arrangement. Proceeding from the at least one second device 119, the second space of finite extent has for example an extent of up to 100 mm, of up to 50 mm, of up to 20 mm, of up to 10 mm, of up to 1 mm, of up to 500 μm, of up to 300 μm, of up to 100 μm or of up to 10 μm. However, the invention is not restricted to such extents. On the contrary, the extent of the second space of finite extent may have any value suitable for the invention. In particular, the extent of the second space of finite extent is variable. By way of example, the extent of the second space of finite extent is dependent on the speed of movement of the first device 114, 125 and/or of the at least one second device 119. In addition or as an alternative, the extent of the second space of finite extent is dependent on the distance between the first device 114, 125 and the at least one second device 119. Provision is made in particular for the extent of the second space of finite extent to become larger as the distance between the first device 114, 125 and the at least one second device 119 increases, and for the extent of the second space of finite extent to become smaller as the distance between the first device 114, 125 and the at least one second device 119 decreases. In addition or as an alternative, provision is made for the extent of the second space of finite extent to become larger as the speed of movement of the first device 114, 125 and/or of the at least one second device 119 increases, and for the extent of the second space of finite extent to become smaller as the speed of movement of the first device 114, 125 and/or of the at least one second device 119 decreases.

By way of example, the first space of finite extent of the first surface arrangement and/or the second space of finite extent of the second surface arrangement are/is used when carrying out method steps of the method according to the system described herein, in particular in the check, explained below, to determine whether, in a movement process of the first device 114, 125, the first surface arrangement and the second surface arrangement have at least one common point. In particular, provision is made to check whether the first space of finite extent and the second space of finite extent have a common point.

Moreover, the first structure data and/or the second structure data include for example information about at least one transformation of the first device 114, 125 and/or of the at least one second device 119. The transformation of the first device 114, 125 and/or of the at least one second device 119 within the meaning of the system described herein may be understood to mean for example a movement of the first device 114, 125 and/or of the at least one second device 119. During the movement, the first device 114, 125 and/or the at least one second device 119 experiences the transformation, since a property of the first device 114, 125 and/or of the at least one second device 119, namely a positioning in a space, changes. In particular, the transformation may be understood to mean a movement of the first device 114, 125 and/or of the at least one second device 119 along a movement path. In this case, the movement path, within the meaning of the system described herein, may be understood to mean a sequence of points in space, where the points are embodied such that it is possible to carry out a movement from a first point of the sequence of points to a last point of the sequence of points. In the movement from a first point of the sequence of points to a last point of the sequence of points, the points of the sequence of points may be run through in succession. By way of example, only part of the movement path may also be understood to be the movement path. In this case, only some of the points of the sequence of points are run through in the movement. Points of the sequence of points are also referred to below as intermediate points. In addition or as an alternative, the transformation of the first device 114, 125 and/or of the at least one second device 119 within the meaning of the system described herein may be understood to mean a deformation of the first device 114, 125 and/or of the at least one second device 119. As an alternative, the transformation of the first device 114, 125 and/or of the at least one second device 119 within the meaning of the system described herein might not be understood to mean a deformation of the first device 114, 125 and/or of the at least one second device 119. In this case, the transformation of the first device 114, 125 and/or of the at least one second device 119 within the meaning of the system described herein may be understood to mean the movement of the first device 114, 125 and/or of the at least one second device 119.

The deformation of the first device 114, 125 and/or of the at least one second device 119 within the meaning of the system described herein may be understood to mean for example a change of the surface arrangement of the first device 114, 125 and/or of the at least one second device 119. In this case, the deformed device may for example remain at a position in space of the deformed device during the deformation. By way of example, during the deformation of the first device 114, 125 within the meaning of the system described herein, the surface arrangement of the first device 114, 125 may change, while a centre of mass of the first device 114, 125 is not spatially changed. In addition or as an alternative, the deformation of the first device 114, 125 and/or of the at least one second device 119 within the meaning of the system described herein may be understood to mean an expansion and/or contraction. Within the meaning of the system described herein, the expansion is understood to mean an increase in spatial extent. Within the meaning of the system described herein, the contraction is understood to mean a decrease in spatial extent. The expansion may be a thermal expansion, for example. In other words, the expansion of the first device 114, 125 and/or of the at least one second device 119 may be brought about by a temperature change of the first device 114, 125 and/or of the at least one second device 119. The contraction may be a thermal contraction, for example. In other words, the contraction of the first device 114, 125 and/or of the at least one second device 119 may be brought about by the temperature change of the first device 114, 125 and/or of the at least one second device 119.

In addition or as an alternative, the deformation of the first device 114, 125 and/or of the at least one second device 119 within the meaning of the system described herein may be understood to mean an elongation. Within the meaning of the system described herein, the elongation is understood to mean a change in length of the body on which at least one force acts. The elongation may in this case achieve shortening of the body or lengthening of the body. In addition or as an alternative, the deformation of the first device 114, 125 and/or of the at least one second device 119 within the meaning of the system described herein may be understood to mean a torsion. Within the meaning of the system described herein, the torsion of the body is understood to mean twisting of the body. By way of example, two opposing torques act on the body, leading to twisting of the body.

Furthermore, in addition or as an alternative, the deformation of the first device 114, 125 and/or of the at least one second device 119 within the meaning of the system described herein may include a change of the first device 114, 125 and/or of the at least one second device 119 itself. By way of example, the change of the first device 114, 125 includes a movement of a first part of the first device 114, 125 relative to a second part of the first device 114, 125. If the first device is embodied for example as a movable manipulator, a change of the movable manipulator may include a movement of a wire of the movable manipulator relative to a body of the movable manipulator.

In method step S1 of the method according to the system described herein, the first structure data and the second structure data are provided. Provisioning of the first structure data and of the second structure data may take place in at least one of at least three possible variants.

In a first variant of providing the first structure data and/or the second structure data, the first structure data and/or the second structure data are retrieved from the storage unit 126 of the SEM 100. With regard to the storage unit 126, reference is made to the above statements, which are analogously applicable here as well. In other words, the storage unit 126 stores data corresponding to the first structure data and/or the second structure data. The data corresponding to the first structure data and/or the second structure data may be retrieved from the storage unit 126. In addition or as an alternative, the first structure data and/or the second structure data may be computed from data stored in the storage unit 126.

In a second variant of providing the first structure data and/or the second structure data, the first structure data and/or the second structure data are input into the control unit 123 of the SEM 100 by a user of the SEM 100 using an input unit of the SEM 100. The input unit is in this case embodied such that the input unit is suitable for inputting data. By way of example, the input unit is embodied as a keyboard, as a joystick, as at least one sensor already mentioned above and/or as at least one abovementioned detector. In addition or as an alternative, the input unit may be embodied as a camera that is designed, using a computer program, to capture gestures made by the user and to interpret the gestures as data. Furthermore, in addition or as an alternative, the input unit may be embodied as a unit that allows data to be read from a file. In other words, the first structure data and/or the second structure data are provided using the input unit.

In a third variant of providing the first structure data and/or the second structure data, the first structure data and/or the second structure data are recorded using at least one detector and/or at least one sensor of the SEM 100. By way of example, the detector 140 that records structure data is used as the detector and/or the sensor 141 that records structure data is used as the sensor. The detector 140 that records structure data is in this case embodied such that the detector 140 is designed to detect interaction particles and/or interaction radiation. The interaction particles and/or interaction radiation arise/arises from an interaction of the primary electron beam with the first device 114, 125 and/or with the at least one second device 119 when the primary electron beam is incident on the first device 114, 125 and/or on the at least one second device 119. As a consequence of the interaction, in particular electrons are emitted by the first device 114, 125 and/or by the at least one second device 119 (so-called secondary electrons) and electrons of the primary electron beam are backscattered (so-called backscattered electrons). The secondary electrons and the backscattered electrons are detected and used for image generation. An image representation of the first device 114, 125 to be examined and/or of the at least one second device 119 to be examined is thus obtained. Furthermore, interaction radiation, for example x-ray radiation or cathodoluminescence, is generated during the interaction, and is for example detected by way of the detector 140 that records structure data and subsequently evaluated in order to analyse the first device 114, 125 and/or the at least one second device 119.

The sensor 141 that records structure data is embodied here such that the sensor 141 is designed to capture physical properties of the first device 114, 125 and/or of the at least one second device 119. By way of example, the sensor 141 that records structure data may capture electromagnetic radiation scattered at the first device 114, 125 and/or the at least one second device 119. In particular, the electromagnetic radiation may in this case include at least one wavelength from a wavelength range from 400 nm to 2000 nm.

It is pointed out that the first structure data and the second structure data may be provided using various ones of the abovementioned variants. In other words, the first structure data may be provided by the variant that does not correspond to the variant used to provide the second structure data. By way of example, the first structure data are provided by recording the first structure data using the at least one detector 140 that records structure data, and the second structure data are provided by retrieving the second structure data from the storage unit 126 of the SEM 100.

The first and/or the second structure data may be provided for example in the form of CAD data. In other words, there may be CAD models from which information relating to the first structure data and/or the second structure data may be taken.

In a method step S2 of the method according to the system described herein, a target arrangement for the first device 114, 125 is determined using the control unit 123 of the SEM 100. In this case, the target arrangement within the meaning of the system described herein is for example a relative arrangement of the first device 114, 125 with respect to the at least one second device 119. In other words, the target arrangement specifies for example a desired arrangement to be achieved of the first device 114, 125 with respect to the at least one second device 119. By way of example, the target arrangement for the first device 114, 125 is determined by inputting target data into the control unit 123 of the SEM 100 and/or by loading the target data from the storage unit 125 into the control unit 123 of the SEM 100. In particular, target data are input using the input unit or an input device for the control unit 123. The target data within the meaning of the system described herein are suitable for defining the target arrangement. By way of example, the target data includes spatial coordinates of the first device 114, 125 relative to the at least one second device 119, where the spatial coordinates of the first device 114, 125 relative to the at least one second device 119 describe at least one position of the first device 114, 125 relative to the at least one second device 119 in the target arrangement. In addition or as an alternative, the target arrangement for the first device 114, 125 may be determined by capturing target data by way of the at least one sensor and/or the at least one detector. Furthermore, in addition or as an alternative, the target arrangement for the first device 114, 125 may be determined by computing target data. By way of example, the target data may be computed using a computer program that applies image recognition methods. With regard to the control unit 123 and the input unit, reference is made to the above statements, which are analogously applicable here as well.

In a method step S3 of the method according to the system described herein, at least one movement path of the first device 114, 125 to reach the target arrangement for the first device 114, 125 is provided using the processor unit 127. With regard to the movement path, reference is made to the above statements, which are analogously applicable here as well.

Providing the movement path includes determining the movement path, for example by defining the intermediate points, where the intermediate points are points in space that are able to be used to describe the movement path (in this respect, see also the above statements regarding the movement path). By way of example, the intermediate points may be described by spatial coordinates. The movement path may be determined for example by the shortest distance between the intermediate points.

When providing the movement path, for example, the processor unit 127 generates data describing movement paths. By way of example, the data describe a multiplicity of movement paths. In particular, an individual movement path may be selected from the multiplicity of movement paths. The individual movement path may be selected from the multiplicity of movement paths for example based on predefinable criteria. The predefinable criteria for selecting the individual movement path may be formed for example by a length of the individual movement path and/or a duration of a movement process associated with the individual movement path and/or a distance between the individual movement path and surrounding devices and/or a location of the individual movement path. A movement process within the meaning of the system described herein is understood here to mean carrying out a movement. In other words, for example, the movement of the first device 114, 125 along the movement path is referred to as a movement process. By way of example, the movement process is controlled by the control unit 123 of the SEM 100 using the object stage 122. In other words, the movement process is carried out for example in automated fashion.

In a method step S4 of the method according to the system described herein, the movement path of the first device 114, 125 within the SEM 100 is modelled using the processor unit 127. In other words, the movement path is modelled computationally. The provision of the movement path and the modelling of the movement path may be contained within a single method step or be identical. The first structure data, the second structure data and the target arrangement for the first device 114, 125 are used for the modelling. With regard to the movement path, reference is made to the above statements, which are analogously applicable here as well. In particular, part of the movement path may also be understood to be the movement path within the meaning of the system described herein. Modelling the movement path within the meaning of the system described herein includes determining the movement path. In other words, the modelling may be understood to mean simulating the movement path.

The provision and/or modelling of the at least one movement path of the first device 114, 125 within the SEM 100 using the processor unit 127 may be repeated. By way of example, the provision and/or modelling of the at least one movement path of the first device 114, 125 within the SEM 100 using the processor unit 127 may be repeated when the user of the SEM 100 makes an input, where the input aims to repeat the provision and/or modelling. By way of example, the inputting of a new target arrangement using the input unit may target the repetition of the provision and/or of the modelling.

In a method step S5 of the method according to the system described herein, a check is carried out, on the one hand, to determine whether the modelling of the movement path of the first device 114, 125 within the SEM 100 has the result, at at least one point of the modelled movement path, that the at least one first surface arrangement of the first device 114, 125 and the at least one second surface arrangement of the at least one second device 119 have at least one common point when carrying out a movement process along the modelled movement path. On the other hand, in the method step S5 of the method according to the system described herein, a check is carried out to determine whether the modelling of the movement path of the first device 114, 125 within the SEM 100 has the result that the at least one first surface arrangement of the first device 114, 125 and the at least one second surface arrangement of the at least one second device 119 are at a shortest distance from one another when carrying out the movement process along the modelled movement path, where the shortest distance is smaller than a predefinable minimum distance, and where the at least one first surface arrangement of the first device 114, 125 and the at least one second surface arrangement of the at least one second device 119 do not, however, have a common point when carrying out the movement process along the modelled movement path. Within the meaning of the system described herein, a distance between a first body and a second body is understood to mean a shortest connection of all possible connections between any point on a surface of the first body and any point on a surface of the second body. Of all distances between the at least one first surface arrangement of the first device 114, 125 and the at least one second surface arrangement of the at least one second device 119 that are achieved when carrying out the movement process along the modelled movement path, a smallest possible distance is referred to as a shortest distance. The predefinable minimum distance may be provided for example through retrieval from the storage unit 126 and/or by an input from the user of the SEM 100 using the input unit. By way of example, the predefinable minimum distance is not less than 10 μm.

In other words, in method step S5 of the method according to the system described herein, a check is carried out to determine whether there is a match between at least one first point of the at least one first surface arrangement of the first device 114, 125 and at least one second point of the at least one second surface arrangement of the at least one second device 119, when the movement process is carried out along the modelled movement path. Moreover, a check is carried out to determine whether, during the movement process along the modelled movement path, there is a state in which the shortest distance between the at least one first surface arrangement of the first device 114, 125 and the at least one second surface arrangement of the at least one second device 119 falls below the predefinable minimum distance. In other words, a check is carried out to determine whether the at least one first surface arrangement of the first device 114, 125 and the at least one second surface arrangement of the at least one second device 119, when carrying out the movement process along the modelled movement path, approach closer to one another than specified by the predefinable minimum distance. The predefinable minimum distance may for example be retrieved from the storage unit 126. In addition or as an alternative, the predefinable minimum distance may be determined by the input from the user of the SEM 100 using the input unit.

In an optional method step S6 of the method according to the system described herein, a result of the check is stored in the storage unit 126 as collision data. In other words, information about the check explained above is stored in the storage unit 126 as the collision data. With regard to the storage unit 126, reference is made to the above statements. By way of example, the collision data includes information about the common point along the modelled movement path that both the at least one first surface arrangement of the first device 114, 125 and the at least one second surface arrangement of the at least one second device 119 have when carrying out the movement process along the modelled movement path. By way of example, the collision data includes information about the shortest distance between the at least one first surface arrangement of the first device 114, 125 and the at least one second surface arrangement of the at least one second device 119 that is achieved during the movement process along the modelled movement path and falls below the predefinable minimum distance. By way of example, the stored collision data may be displayed on the display unit 124.

In a following method step of the method according to the system described herein, a distinction is made based on the result of the check in method step S5, which has optionally been stored in the form of collision data in method step S6.

If a common point is identified, in a method step in the form of a distinguishing step Q1, that the at least one first surface arrangement of the first device 114, 125 and the at least one second surface arrangement of the at least one second device 119 have the at least one common point when carrying out the movement process along the modelled movement path, a method step S6A follows the method step S6. In the method step S6A of the method according to the system described herein, at least one of the following method steps is carried out:
(a) displaying a message on the display unit 124 of the SEM 100;
(b) discarding or aborting the movement process of the first device 114, 125 along the provided movement path. If the movement process of the first device 114, 125 along the provided movement path has not yet been started, the movement process is accordingly not initiated. However, if the movement process of the first device 114, 125 along the provided movement path has already been started, the movement process is aborted;
(c) discarding or switching the movement process of the first device 114, 125 along the provided movement path to a further movement process. If the movement process of the first device 114, 125 along the provided movement path has not yet been started, the movement process is accordingly not initiated. However, if the movement process of the first device 114, 125 along the provided movement path has already been started, the movement process is switched to a further movement process. By way of example, the switching of the movement process of the first device 114, 125 includes restricting the further movement process to predefinable degrees of freedom of the movement of the first device 114, 125, in particular to one or more predefinable translational movements and/or rotational movements;
(d) carrying out the movement process of the first device 114, 125 along the provided movement path using the object stage 122;
(e) changing a speed of the movement process of the first device 114, 125 along the provided movement path using the movement device in the form of the object stage 122 to move the first device 114, 125.

The abovementioned further movement process may be for example a manual movement process, that is to say a movement process in which the movement is controlled by an input from the user. In addition or as an alternative, the further movement process may be a movement process of the first device 114, 125 along a further movement path, where the further movement path arises from the provided movement path, for example, such that the further movement path is a displacement or rotation of the provided movement path. By way of example, the further movement path arises from the provided movement path such that all points of the provided movement path are displaced in a direction, for example a direction parallel to an optical axis of the SEM 100.

The abovementioned display unit 124 within the meaning of the system described herein is designed to display data. By way of example, the display unit 124 is used to communicate, to the user of the SEM 100, information stating that the at least one first surface arrangement of the first device 114, 125 and the at least one second surface arrangement of the at least one second device 119 have the at least one common point when carrying out the movement process along the modelled movement path.

The abovementioned aborting of the movement process of the first device 114, 125 along the provided movement path includes for example stopping the movement process of the first device 114, 125 along the provided movement path. In addition or as an alternative, aborting the movement process of the first device 114, 125 along the provided movement path includes for example not starting the movement process of the first device 114, 125 along the provided movement path.

In the abovementioned switching of the movement process of the first device 114, 125 along the provided movement path to the further movement process, there is no further control of the movement process of the first device 114, 125 along the provided movement path using the target data.

In the abovementioned further movement process within the meaning of the system described herein, the first device 114, 125 is moved for example by the input from the user of the SEM 100 using the input unit and the control unit 123. In other words, the user of the SEM 100 controls the movement of the first device 114, 125. Switching the movement process of the first device 114, 125 along the provided movement path to the further movement process includes for example aborting the movement process of the first device 114, 125 along the provided movement path.

In the abovementioned carrying out of the movement process of the first device 114, 125 along the provided movement path using the object stage 122, for example, the first device 114, 125 and the at least one second device 119 may be brought into contact, since the at least one first surface arrangement of the first device 114, 125 and the at least one second surface arrangement of the at least one second device 119 have the at least one common point when carrying out the movement process along the modelled movement path.

A decision as to whether, as a result of the abovementioned identification from distinguishing step Q1 that the at least one first surface arrangement of the first device 114, 125 and the at least one second surface arrangement of the at least one second device 119 have the at least one common point when carrying out the movement process along the modelled movement path, at least one of method steps (a) to (e) is carried out in the method step S6A (that is to say (a) displaying the message on the display unit 124 of the SEM 100 and/or (b) discarding or aborting the movement process of the first device 114, 125 along the provided movement path and/or (c) discarding or switching the movement process of the first device 114, 125 along the provided movement path to a further movement process and/or (d) carrying out the movement process of the first device 114, 125 along the provided movement path using the object stage 122 and/or (e) changing a speed of the movement process of the first device 114, 125 along the provided movement path using the object stage 122 to move the first device 114, 125) may be stored for example in the storage unit 126. In other words, the storage unit 126 contains for example information such that the message is always displayed on the display unit 124 of the SEM 100 and the movement process of the first device 114, 125 along the provided movement path is always aborted as soon as the at least one first surface arrangement of the first device 114, 125 and the at least one second surface arrangement of the at least one second device 119 have the at least one common point when carrying out the movement process along the modelled movement path. In addition or as an alternative, the decision may be made by the user of the SEM 100. In this case, for example, the message is displayed on the display unit 124 of the SEM 100, linked to at least one selection option as to whether the movement process of the first device 114, 125 along the provided movement path should be discarded and/or the movement process of the first device 114, 125 along the provided movement path should be aborted and/or the movement process of the first device 114, 125 along the provided movement path should be switched to a further movement process and/or a speed of the movement process of the first device 114, 125 along the provided movement path should be changed. The displaying of the message may include for example information about the arrangement and/or an expected distance between the first device 114, 125 and the at least one second device 119 and/or a visualization of the arrangement and/or a warning message. By making an input using the input unit, the user of the SEM 100 may make a selection from the at least one selection option. In addition or as an alternative, the user of the SEM 100 may select to carry out the movement process of the first device 114, 125 along the movement path using the object stage 122, for example in order to deliberately bring the first device 114, 125 into mechanical contact with the at least one second device 119.

If it is identified, in distinguishing step Q1, that the at least one first surface arrangement of the first device 114, 125 and the at least one second surface arrangement of the at least one second device 119 do not have a common point when carrying out the movement process along the modelled movement path, a method step in the form of a distinguishing step Q2 follows. If it is identified, in distinguishing step Q2, that a first location of the at least one first surface arrangement of the first device 114, 125 and a second location of the at least one second surface arrangement of the at least one second device 119 are at the shortest distance when carrying out the movement process along the modelled movement path, where the shortest distance is smaller than the predefinable minimum distance, a method step S6B follows the method step S6. In the method step S6B of the method according to the system described herein, at least one of the following steps is carried out:
(a) displaying the message on the display unit 124 of the SEM 100;
(b) discarding the movement process of the first device 114, 125 along the provided movement path or changing a speed of the movement process of the first device 114, 125 along the provided movement path. If the movement process of the first device 114, 125 along the provided movement path has not yet been started, the movement process is accordingly not initiated. However, if the movement process of the first device 114, 125 along the provided movement path has already been started, the speed of the movement process of the first device 114, 125 along the provided movement path is changed. By way of example, the speed is changed as a function of the shortest distance. In particular, the speed becomes lower the smaller the distance between the first device 114, 125 and the second device 119;
(c) discarding the movement process of the first device 114, 125 along the provided movement path or aborting the movement process of the first device 114, 125 along the provided movement path. If the movement process of the first device 114, 125 along the provided movement path has not yet been started, the movement process is accordingly not initiated. However, if the movement process of the first device 114, 125 along the provided movement path has already been started, the movement process of the first device 114, 125 along the provided movement path is aborted;
(d) discarding the movement process of the first device 114, 125 along the provided movement path or switching the movement process of the first device 114, 125 along the provided movement path to a further movement process. If the movement process of the first device 114, 125 along the provided movement path has not yet been started, the movement process is accordingly not initiated. However, if the movement process of the first device 114, 125 along the provided movement path has already been started, the movement process of the first device 114, 125 along the provided movement path is switched to a further movement process. By way of example, the switching of the movement process of the first device 114, 125 includes restricting the further movement process to predefinable degrees of freedom of the movement of the first device 114, 125, in particular to one or more predefinable translational movements and/or rotational movements;
(e) carrying out the movement process of the first device 114, 125 along the provided movement path using the object stage 122.

With regard to the displaying of the message on the display unit 124 of the SEM 100, the discarding of the movement process of the first device 114, 125 along the provided movement path, the aborting of the movement process of the first device 114, 125 along the provided movement path, the switching of the movement process of the first device 114, 125 along the provided movement path to a further movement process and the carrying out of the movement process of the first device 114, 125 along the provided movement path, reference is made to the above statements, which are analogously applicable here as well. When changing the speed of the movement process of the first device 114, 125 along the provided movement path, the first device 114, 125 is moved, for example using the object stage 122, more slowly and/or more quickly in comparison with a customary speed of the movement process along the provided movement path. By way of example, the speed is changed as a function of the shortest distance. The customary speed of the movement process and/or the changed speed of the movement process are/is stored for example in the storage unit 126. In addition or as an alternative, the customary speed of the movement process and/or the changed speed of the movement process may be predefined by the input from the user of the SEM 100.

A decision as to whether, as a result of the abovementioned identification from distinguishing step Q2 that the first location of the at least one first surface arrangement of the first device 114, 125 and the second location of the at least one second surface arrangement of the at least one second device 119 are at the shortest distance when carrying out the movement process along the modelled movement path, where the shortest distance is smaller than the predefinable minimum distance and where the at least one first surface arrangement of the first device 114, 125 and the at least one second surface arrangement of the at least one second device 119 do not, however, have the common point when carrying out the movement process along the modelled movement path (in accordance with the previous identification from Q1), at least one of method steps (a) to (e) is carried out (that is to say (a) displaying the message on the display unit 124 of the SEM 100 and/or (b) discarding the movement process of the first device 114, 125 along the provided movement path or changing the speed of the movement process of the first device 114, 125 along the provided movement path and/or (c) discarding the movement process of the first device 114, 125 along the provided movement path or aborting the movement process of the first device 114, 125 along the provided movement path and/or (d) discarding the movement process of the first device 114, 125 along the provided movement path or switching the movement process of the first device 114, 125 along the provided movement path to a further movement process and/or (e) carrying out the movement process of the first device along the provided movement path using the object stage 122) may be stored for example in the storage unit 126 and/or be determined by the input from the user of the SEM 100. With regard to the storage of the decision in the storage unit 126 and the decision by the user of the SEM 100, reference is made to the above statements, which are analogously applicable here as well.

If it is identified, in distinguishing step Q2, that the first location of the at least one first surface arrangement of the first device 114, 125 and the second location of the at least one second surface arrangement of the at least one second device 119 are at the shortest distance when carrying out the movement process along the modelled movement path, where the shortest distance is greater than or identical to the predefinable minimum distance and where the at least one first surface arrangement of the first device 114, 125 and the at least one second surface arrangement of the at least one second device 119 therefore also do not have the common point when carrying out the movement process along the modelled movement path, a method step S6C follows the method step S6. In the method step S6C of the method according to the system described herein, the movement process of the first device 114, 125 along the provided movement path is carried out using the object stage 122 to move the first device 114, 125.

In a further embodiment of the method according to the system described herein, provision is made, in addition or as an alternative, for at least one of the following units to be used as the first device and/or as the at least one second device: the object 125, the object stage 122, the object holder 114, the micromanipulator, the sample chamber 120, the lock, the light source, the beam column (for example in the form of the beam guiding tube 104), the capture device in the form of at least one of the detectors 116, 117, 119, 121, 140, 500, the capture device in the form of the sensor 141, a gas injection system, a charge compensation device, a camera, a lock bar, a gripper, the scanning system 105, 106, 107, 115, 130, the electrode 112, 113, the cable, the hose, the scanning force microscope, the microtome, the plasma cleaner, the Faraday cup, the aperture unit 108, 109, the objective cap, the at least one part of the beam column 104, and the SEM 100. With regard to the capture device 116, 117, 119, 121, 140, 141, 500, reference is made to the above statements, which are analogously applicable here as well.

In other words, any element within the SEM 100 and/or the SEM 100 itself that is suitable within the meaning of the system described herein may be used as the first device and/or as the at least one second device. An element within the meaning of the system described herein is suitable as the first device if the element is able to be arranged movably within the SEM 100. By way of example, the element within the meaning of the system described herein is suitable as a first device if the element is designed such that the element moves relative to another element using the object stage 122. In this case, the movement may be automated, for example by virtue of the movement being carried out using the control unit 123. In addition or as an alternative, the movement may be manual, for example if the movement is carried out through manual actuation of the user of the SEM 100. An element within the meaning of the system described herein is suitable as the at least one second device if the element is able to be arranged within the SEM 100 and/or is the SEM 100. In particular, an element within the meaning of the system described herein is suitable as the at least one second device if, owing to the movement of the first device, the first device and the at least one second device may collide and/or be at the shortest distance that falls below the predefinable minimum distance.

By way of example, at least one of the following units may, in addition or as an alternative, be used as the at least one second device: the SEM 100, the beam guiding tube 104, the first condenser lens 105, the second condenser lens 106, the first objective lens 107, the first aperture unit 108, the second aperture unit 109, the single electrode 112, the tube electrode 113, the object holder 114, the second deflection unit 115, the first detector 116, the second detector 117, the radiation detector 119, the sample chamber 120, the third detector 121, the object stage 122, the object 125, the first deflection unit 130, the detector 140 that records structure data, the sensor 141 that records structure data, the combination apparatus 200, the sample chamber 201, the ion beam apparatus 300, the condenser lens 303, the second objective lens 304, the adjustable or selectable aperture unit 306, the first electrode arrangement 307, the second electrode arrangement 308, the particle beam apparatus 400 including a corrector unit, the first electrostatic lens 405, the second electrostatic lens 406, the third electrostatic lens 407, the magnetic deflection unit 408, the first electrostatic beam deflection unit 409, the first multi-pole unit 409A, the second multi-pole unit 409B, the beam deflection device 410, the first magnetic sector 411A, the second magnetic sector 411B, the third magnetic sector 411C, the fourth magnetic sector 411D, the fifth magnetic sector 411E, the sixth magnetic sector 411F, the seventh magnetic sector 411G, the first mirror electrode 413A, the second mirror electrode 413B, the third mirror electrode 413C, the electrostatic mirror 414, the fourth electrostatic lens 415, the second electrostatic beam deflection unit 416, the third multi-pole unit 416A, the fourth multi-pole unit 416B, the third electrostatic beam deflection unit 417, the fifth electrostatic lens 418, the fifth multi-pole unit 418A, the sixth multi-pole unit 418B, the first analysis detector 419, the beam guiding tube 420, the objective lens 421, the magnetic lens 422, the sixth electrostatic lens 423, the object stage 424, the object 425, the sample chamber 426, the second analysis detector 428, the scanning device 429, the further magnetic deflection unit 432 and the chamber detector 500.

In yet another embodiment of the method according to the system described herein, provision is made, in addition or as an alternative, for the movement path of the first device 114, 125 within the SEM 100 to be provided and/or modelled taking into account a predefinable minimum distance, such that a distance between the first device 114, 125 and the at least one second device 119 always corresponds at least to the predefinable minimum distance. In other words, the movement path of the first device 114, 125 within the SEM 100 is provided and/or modelled such that any distance between a first position on the at least one first surface arrangement of the first device 114, 125 and a second position on the at least one second surface arrangement of the at least one second device 119 does not fall below the minimum distance when carrying out the movement process along the modelled movement path. In yet other words, the movement path of the first device 114, 125 within the SEM 100 is provided and/or modelled such that there is no collision between the first device 114, 125 and the at least one second device 119, and the first device 114, 125 and the at least one second device 119 are at a distance from one another, at all times, that corresponds at least to the minimum distance. It is pointed out that a distance within the meaning of the system described herein denotes a physical distance. In other words, the distance within the meaning of the system described herein may be greater than zero if the first device 114, 125 and the at least one second device 119 are not in contact with one another. Within the meaning of the system described herein, the distance may be zero if the first device 114, 125 and the at least one second device 119 are in contact with one another. Within the meaning of the system described herein, the distance may be less than zero if the first device 114, 125 and the at least one second device 119 are in contact with one another and a pressure is also exerted between the first device 114, 125 and the at least one second device 119. By way of example, the first device 114, 125 and the at least one second device 119, by carrying out the movement process, may be arranged on one another such that the first device 114, 125 is arranged with pressure on the at least one second device 119, for example in order to achieve a connection between the first device 114, 125 and the at least one second device 119.

The minimum distance may be for example the predefinable minimum distance. In this case, the movement path of the first device 114, 125 within the SEM 100 is provided and/or modelled such that the first device 114, 125 is always at a shortest distance from the at least one second device 119 that is greater than the predefinable minimum distance. The minimum distance may be provided for example through retrieval from the storage unit 126 and/or by an input from the user of the SEM 100 using the input unit. By way of example, the minimum distance is not less than 10 μm. With regard to the shortest distance and the minimum distance, reference is made to the above statements, which are analogously applicable here as well.

Furthermore, in addition or as an alternative, the method according to the system described herein may have at least one feature mentioned elsewhere herein or a combination of at least two of the features mentioned elsewhere herein.

None of the embodiments of the method according to the invention are restricted to the orders of the method steps presented above. On the contrary, any orders of the method steps suitable for solving the problem within the meaning of the invention may be used. As an alternative or in addition, provision is also made for the parallel implementation of at least two method steps. As an alternative or in addition, provision is also made for the omission of individual method steps.

The features of the invention disclosed in the present description, in the drawings and in the claims may be essential for the realization of the invention in the various embodiments thereof both individually and in any desired combinations. The invention is not restricted to the embodiments described and may be varied within the scope of the claims and taking into account the knowledge of those skilled in the relevant art.

1. A method for operating a particle beam apparatus for imaging, processing and/or analyzing an object, comprising:
providing first structure data and second structure data, wherein the first structure data includes information about at least one first surface arrangement of a first device within the particle beam apparatus, wherein the second structure data includes information about at least one second surface arrangement of at least one second device within the particle beam apparatus, wherein the first structure data and/or the second structure data includes information about at least one transformation of the first device and/or of the at least one second device, and wherein providing the first structure data and the second structure data includes retrieval from a storage unit for the particle beam apparatus, a user of the particle beam apparatus making an input into a control unit of the particle beam apparatus using an input unit, and/or recording the first structure data and/or the second structure data using at least one detector and/or at least one sensor of the particle beam apparatus;
determining a target arrangement for the first device using the control unit of the particle beam apparatus;
providing at least one movement path of the first device to reach the target arrangement for the first device using a processor unit;
modelling the movement path of the first device within the particle beam apparatus using a processor unit wherein the first structure data, the second structure data and the target arrangement for the first device are used in the modelling;
carrying out a check, using the processor unit to determine whether the at least one first surface arrangement of the first device and the at least one second surface arrangement of the at least one second device, when carrying out a movement process of the first device along the modelled movement path either have at least one common point or are at a shortest distance, wherein the shortest distance is smaller than a predefinable minimum distance, and wherein the at least one first surface arrangement of the first device and the at least one second surface arrangement of the at least one second device do not have a common point;
in response to the at least one first surface arrangement of the first device and the at least one second surface arrangement of the at least one second device having the at least one common point when carrying out the movement process of the first device along the modelled movement path, performing at least one of the following:
displaying a message on a display unit the particle beam apparatus;
discarding or aborting the movement process of the first device along the provided movement path;
discarding or switching the movement process of the first device along the provided movement path to a further movement process;
carrying out the movement process of the first device along the provided movement path using a movement device to move the first device;
changing a speed of the movement process of the first device along the provided movement path using the movement device to move the first device;
in response to a first location of the at least one first surface arrangement of the first device and a second location of the at least one second surface arrangement of the at least one second device being at the shortest distance when carrying out the movement process along the modelled movement path, wherein the at least one first surface arrangement of the first device and the at least one second surface arrangement of the at least one second device do not have the common point when carrying out the movement process along the modelled movement path, performing at least one of the following:
displaying a message on a display unit of the particle beam apparatus;
discarding the movement process of the first device along the provided movement path or changing a speed of the movement process of the first device along the provided movement path;
discarding the movement process of the first device along the provided movement path or aborting the movement process of the first device along the provided movement path;
discarding the movement process of the first device along the provided movement path or switching the movement process of the first device along the provided movement path to a further movement process;
carrying out the movement process of the first device along the provided movement path using a movement device to move the first device; and
in response to a first location of the at least one first surface arrangement of the first device and a second location of the at least one second surface arrangement of the at least one second device being longer distance when carrying out the movement process along the modelled movement path, wherein the longer distance is greater than or identical to the predefinable minimum distance, carrying out the movement process of the first device along the provided movement path using a movement device to move the first device.

2. The method according to claim 1, wherein a result of the check is stored in the storage unit as collision data.

3. The method according to Claim wherein at least one of the following units is used as the first device and/or as the at least one second device: the object, an object stage, an object holder, a micromanipulator, a sample chamber, a lock, a light source, a beam column, a capture device, a gas injection system, a charge compensation device, a camera, a lock bar, a gripper, a scanning system, an electrode a cable, a hose, a scanning force microscope, a microtome, a plasma cleaner, a Faraday cup, an aperture unit an objective cap, at least part of the beam column an ion beam apparatus and the particle beam apparatus.

4. The method according to claim 1, wherein the movement path of the first device within the particle beam apparatus is provided and/or modelled taking into account a predefinable minimum distance, such that a distance between the first device and the at least one second device always corresponds at least to the predefinable minimum distance.

5. A non-transitory computer readable medium containing program code that is able to be loaded into a processor unit of a particle beam apparatus and that, when executed, controls the particle beam apparatus, the program code comprising:
executable code that provides first structure data and second structure data, wherein the first structure data includes information about at least one first surface arrangement of a first device within the particle beam apparatus, wherein the second structure data includes information about at least one second surface arrangement of at least one second device within the particle beam apparatus, wherein the first structure data and/or the second structure data includes information about at least one transformation of the first device and/or of the at least one second device, and wherein providing the first structure data and the second structure data includes retrieval from a storage unit for the particle beam apparatus, a user of the particle beam apparatus making an input into a control unit of the particle beam apparatus using an input unit, and/or recording the first structure data and/or the second structure data using at least one detector and/or at least one sensor of the particle beam apparatus;
executable code that determines a target arrangement for the first device using the control unit of the particle beam apparatus;
executable code that provides at least one movement path of the first device to reach the target arrangement for the first device using a processor unit;
executable code that models the movement path of the first device within the particle beam apparatus using a processor unit, wherein the first structure data, the second structure data and the target arrangement for the first device are used in the modelling;
executable code that carries out a check, using the processor unit, to determine whether the at least one first surface arrangement of the first device and the at least one second surface arrangement of the at least one second device, when carrying out a movement process of the first device along the modelled movement path either have at least one common point or are at a shortest distance, wherein the shortest distance is smaller than a predefinable minimum distance, and wherein the at least one first surface arrangement of the first device and the at least one second surface arrangement of the at least one second device do not have a common point;
executable code that, in response to the at least one first surface arrangement of the first device and the at least one second surface arrangement of the at least one second device having the at least one common point when carrying out the movement process of the first device along the modelled movement path, performs at least one of the following:
displays a message on a display unit of the particle beam apparatus;
discards or aborts the movement process of the first device along the provided movement path;
discards or switches the movement process of the first device along the provided movement path to a further movement process;
carries out the movement process of the first device along the provided movement path using a movement device to move the first device;
changes a speed of the movement process of the first device along the provided movement path using the movement device to move the first device;
executable code that, in response to a first location of the at least one first surface arrangement of the first device and a second location of the at least one second surface arrangement of the at least one second device being at the shortest distance when carrying out the movement process along the modelled movement path, wherein the at least one first surface arrangement of the first device and the at least one second surface arrangement of the at least one second device do not have the common point when carrying out the movement process along the modelled movement path, performs at least one of the following:
displays a message on a display unit of the particle beam apparatus;
discards the movement process of the first device along the provided movement path or changing a speed of the movement process of the first device along the provided movement path;
discards the movement process of the first device along the provided movement path or aborting the movement process of the first device along the provided movement path;
discards the movement process of the first device along the provided movement path or switching the movement process of the first device along the provided movement path to a further movement process;
carries out the movement process of the first device along the provided movement path using a movement device to move the first device; and
executable code that, in response to a first location of the at least one first surface arrangement of the first device and a second location of the at least one second surface arrangement of the at least one second device being at a longer distance when carrying out the movement process along the modelled movement path, wherein the longer distance is greater than or identical to the predefinable minimum distance, carries out the movement process of the first device along the provided movement path using a movement device to move the first device.

6. A system, comprising:
a storage unit that stores structure data; and
a particle beam apparatus that images, processes and/or analyzes an object, the particle beam apparatus including at least one beam generator that generates at least one particle beam having charged particles, at least one guide device that guides, shapes and/or focuses the particle beam having charged particles onto the object, a first device and at least one second device, at least one movement device that moves the first device at least one control unit that accepts input of the structure data, at least one processor unit, and a non-transitory computer readable medium coupled to the processor and containing program code that, when executed by the processor, controls the particle beam apparatus, the program code comprising:
executable code that provides first structure data and second structure data, wherein the first structure data includes information about at least one first surface arrangement of a first device within the particle beam apparatus, wherein the second structure data includes information about at least one second surface arrangement of at least one second device within the particle beam apparatus, wherein the first structure data and/or the second structure data includes information about at least one transformation of the first device and/or of the at least one second device, and wherein providing the first structure data and the second structure data includes retrieval from a storage unit for the particle beam apparatus, a user of the particle beam apparatus making an input into a control unit of the particle beam apparatus using an input unit, and/or recording the first structure data and/or the second structure data using at least one detector and/or at least one sensor of the particle beam apparatus;
executable code that determines a target arrangement for the first device using the control unit of the particle beam apparatus;
executable code that provides at least one movement path of the first device to reach the target arrangement for the first device using a processor unit;
executable code that models the movement path of the first device within the particle beam apparatus using a processor unit, wherein the first structure data, the second structure data and the target arrangement for the first device are used in the modelling;
executable code that carries out a check, using the processor unit, to determine whether the at least one first surface arrangement of the first device and the at least one second surface arrangement of the at least one second device, when carrying out a movement process of the first device along the modelled movement path either have at least one common point or are at a shortest distance, wherein the shortest distance is smaller than a predefinable minimum distance, and wherein the at least one first surface arrangement of the first device and the at least one second surface arrangement of the at least one second device do not have a common point;
executable code that, in response to the at least one first surface arrangement of the first device and the at least one second surface arrangement of the at least one second device having the at least one common point when carrying out the movement process of the first device along the modelled movement path, performs at least one of the following:
displays a message on a display unit of the particle beam apparatus;
discards or aborts the movement process of the first device along the provided movement path;
discards or switches the movement process of the first device along the provided movement path to a further movement process;
carries out the movement process of the first device along the provided movement path using a movement device to move the first device;
changes a speed of the movement process of the first device along the provided movement path using the movement device to move the first device;
executable code that, in response to a first location of the at least one first surface arrangement of the first device and a second location of the at least one second surface arrangement of the at least one second device being at the shortest distance when carrying out the movement process along the modelled movement path, wherein the at least one first surface arrangement of the first device and the at least one second surface arrangement of the at least one second device do not have the common point when carrying out the movement process along the modelled movement path, performs at least one of the following:
displays a message on a display unit of the particle beam apparatus;
discards the movement process of the first device along the provided movement path or changing a speed of the movement process of the first device along the provided movement path;
discards the movement process of the first device along the provided movement path or aborting the movement process of the first device along the provided movement path;
discards the movement process of the first device along the provided movement path or switching the movement process of the first device along the provided movement path to a further movement process;
carries out the movement process of the first device along the provided movement path using a movement device to move the first device; and
executable code that, in response to a first location of the at least one first surface arrangement of the first device and a second location of the at least one second surface arrangement of the at least one second device being at a longer distance when carrying out the movement process along the modelled movement path, wherein the longer distance is greater than or identical to the predefinable minimum distance, carries out the movement process of the first device along the provided movement path using a movement device to move the first device.

7. The system according to claim 6, wherein the particle beam apparatus has at least one display unit that outputs messages, at least one detector that records the structure data and/or at least one sensor that records the structure data.

8. The system according to claim 6, wherein the first device and/or the at least one second device is/are at least one of the following units: at least one object as an object stage as an object holder, as a micromanipulator, a sample chamber as a lock, a light source, a beam column, a capture device, a gas injection system, a charge compensation device, a camera, a lock bar, a gripper, a scanning system, an electrode, a cable, a hose, a scanning force microscope, a microtome, a plasma cleaner, a Faraday cup, an aperture unit, an objective cap, at least part of the beam column, and the particle beam apparatus.

9. The system according to claim 6, wherein the beam generator is a first beam generator, wherein the particle beam is a first particle beam having first charged particles, wherein the guide device is a first guide device that guides, shapes, and/or focuses the first particle beam onto the first device, and wherein the particle beam apparatus also includes at least one second beam generator that generates at least one second particle beam having second charged particles and at least one second guide device shaping that guides, shapes, and/or focuses the at least one second particle beam onto the first device.

10. The system according to claim 6, wherein the particle beam apparatus is an electron beam apparatus and/or an ion beam apparatus.
